(19) United States
(12) Patent Application Publication
(10) Pub. No.: US 2026/0317622 A1
(43) Pub. Date: Oct. 15, 2026

(54) RARE EARTH ALUMINATE PHOSPHOR, LIGHT EMITTING DEVICE, PROJECTOR, AND METHOD OF MANUFACTURING RARE EARTH ALUMINATE PHOSPHOR

(71) Applicant: NICHIA CORPORATION, Anan-shi (JP)

(72) Inventors: Masato OKAWA, Anan-shi (JP); Yasuaki MASHIMA, Tokushima-shi (JP); Atsushi YOSHINARI, Tokushima-shi (JP)

(73) Assignee: NICHIA CORPORATION, Anan-shi (JP)

(21) Appl. No.: 19/647,846

(22) Filed: Apr. 14, 2026

(30) Foreign Application Priority Data
Apr. 15, 2025 (JP) 2025-066815
Jul. 30, 2025 (JP) 2025-127042

(51) Int. Cl. C09K 11/77; H01S 5/06; H04N 9/31

(52) U.S. Cl. CPC C09K 11/7706; H01S 5/0611; H04N 9/3161

(57) ABSTRACT

A rare earth aluminate phosphor having, on the surface of a first rare earth aluminate phosphor particle having the composition represented by the formula (I), a second rare earth aluminate phosphor part having a composition with a higher Ga molar ratio, the Ga content measured by X-ray fluorescence spectrometry being 0.5% by mass or higher and lower than 3.0% by mass when the total of element R¹, Ce, Al, and element M¹ is 100% by mass.

(R¹₁₋ₙCeₙ)₃(Al₁₋ₘM¹ₘ)₅ₖO₁₂ (I)

(In the formula (I), R¹ is at least one element selected from the group consisting of Y, La, Lu, Gd, and Tb, M¹ is at least one element selected from the group consisting of Ga and Sc, and m, n, and k respectively satisfy 0≤m≤0.012, 0.001≤n≤0.017, and 0.95≤k≤1.10.)

### CROSS-REFERENCE TO RELATED APPLICATION

This application is based on and claims priority to Japanese Patent Application No. 2025-066815, filed on Apr. 15, 2025, and Japanese Patent Application No. 2025-127042, file on Jul. 30, 2025. The entire contents of these applications are incorporated herein by reference.

### TECHNICAL FIELD

The present disclosure relates to a rare earth aluminate phosphor, a light emitting device, a projector, and a method of manufacturing a rare earth aluminate phosphor.

### BACKGROUND

A light emitting device including a light emitting diode (LED) or laser diode (LD), and a wavelength conversion member containing a phosphor that converts the wavelength of the light emitted by the LED or LD has been known. Such a light emitting device is used as a light source for automotive lights, lighting fixtures, backlights for liquid crystal display devices, projectors, and the like. A projector (image projecting device) projects light emitted from a light emitting device on a screen by using a micromirror display device or the like to display a color image. There is a need for a light emitting device used in a projector to have higher fluorescence conversion efficiency.

As a wavelength conversion member included in a light emitting device, Japanese Patent Publication No. 2015-138168, for example, discloses a fluorescence emitting element that uses a sintered body of a cerium-activated garnet structured phosphor in order to reduce thermal resistance.

### SUMMARY

An object of the present disclosure is to provide a rare earth aluminate phosphor enabling a light emitting device to achieve higher emission intensity and higher emission efficiency, a light emitting device, a projector, and a method of manufacturing a rare earth aluminate phosphor.

A first mode of the invention is a rare earth aluminate phosphor that includes:
a first rare earth aluminate phosphor particle having a composition represented by the formula (I) below,
a second rare earth aluminate phosphor part having a composition with a Ga molar ratio higher than a Ga molar ratio in one mole of the composition represented by the formula (I), the second rare earth aluminate phosphor part being present on a surface of first rare earth aluminate phosphor particle, wherein
a Ga content measured by X-ray fluorescence spectrometry in the rare earth aluminate phosphor is 0.5% by mass or higher and lower than 3.0% by mass when a total of at least one element R¹ selected from the group consisting of Y, La, Lu, Gd, and Tb; Ce; Al; and at least one element M¹ selected from the group consisting of Ga and Sc is 100% by mass.

(R¹₁₋ₙCeₙ)₃(Al₁₋ₘM¹ₘ)₅ₖO₁₂ (I)

(In the formula (I), R¹ is at least one element selected from the group consisting of Y, La, Lu, Gd, and Tb, M¹ is at least one element selected from the group consisting of Ga and Sc, and m, n, and k respectively satisfy 0≤m≤0.012, 0.001≤n≤0.017, and 0.95≤k≤1.10.)

A second mode of the invention is a rare earth aluminate phosphor that includes: a first rare earth aluminate phosphor particle having a composition represented by the formula (I) below,
a second rare earth aluminate phosphor part having a composition with a Ga molar ratio higher than a Ga molar ratio in one mole of the composition represented by the formula (I), the second rare earth aluminate phosphor part being present on a surface of first rare earth aluminate phosphor particle, wherein
a Ga content measured by X-ray fluorescence spectrometry in the rare earth aluminate phosphor is 0.5% by mass or higher and lower than 3.0% by mass when a total of at least one element R¹ selected from the group consisting of Y, La, Lu, Gd, and Tb; Ce; Al; and at least one element M¹ selected from the group consisting of Ga and Sc is 100% by mass, and
a first pixel total count is a total number of pixels of one or more of the first rare earth aluminate phosphor particles in an image captured by a scanning electron microscope,
a second total pixel count is a total number of pixels of Ga in one or more of the second rare earth aluminate phosphor parts on the surfaces of the one or more first rare earth aluminate phosphor particles in an image obtained by an energy dispersive X-ray fluorescence spectrometer,
a pixel percentage calculated by dividing the second total pixel count by the first total pixel count is in a range of 5.0% to 80.0%.

(R¹₁₋ₙCeₙ)₃(Al₁₋ₘM¹ₘ)₅ₖO₁₂ (I)

(In the formula (I), R¹ is at least one element selected from the group consisting of Y, La, Lu, Gd, and Tb, M¹ is at least one element selected from the group consisting of Ga and Sc, and m, n, and k respectively satisfy 0≤m≤0.012, 0.001≤n≤0.017, and 0.95≤k≤1.10.)

A third mode of the invention is a light emitting device which includes the rare earth aluminate phosphor described above and a light emitting element having a peak emission wavelength in a range of 350 nm to 500 nm.

A fourth mode of the invention is a projector which includes the light emitting device described above, an image display system, and a projection optical system.

A fifth mode of the invention is a method of manufacturing a rare earth aluminate phosphor that includes:
providing a raw material mixture having a preparatory composition represented by the formula (I) below by mixing a compound containing at least one rare earth element R¹ selected from the group consisting of Y, La, Lu, Gd, and Tb, a compound containing Ce, a compound containing Al, and a compound containing at least one element M¹ selected as needed from Ga and Sc;
obtaining first rare earth aluminate phosphor particles having a composition represented by the formula (I) below by conducting a first heat treatment on the raw material mixture; and
obtaining a rare earth aluminate phosphor including, on the surfaces of the first rare earth aluminate phosphor particles, second rare earth aluminate phosphor parts having a composition with a Ga molar ratio higher than a Ga molar ratio in one mole of the composition represented by the formula (I) below by conducting a second heat treatment on the first rare earth aluminate phosphor particles and a compound containing Ga at a temperature lower than a temperature set in the first heat treatment, wherein
in conducting the second heat treatment, a mixing ratio of the compound containing Ga is 0.5 parts by mass or higher and lower than 5.0 parts by mass per 100 parts by mass of the first rare earth aluminate phosphor particles,
the second heat treatment is not conducted on the first rare earth aluminate phosphor particles together with the compound containing the rare earth element R¹, the compound containing Ce, the compound containing Al, and the compound containing Sc.

(R¹₁₋ₙCeₙ)₃(Al₁₋ₘM¹ₘ)₅ₖO₁₂ (I)

(In the formula (I), R¹ is at least one element selected from the group consisting of Y, La, Lu, Gd, and Tb, M¹ is at least one element selected from the group consisting of Ga and Sc, and m, n, and k respectively satisfy 0≤m≤0.012, 0.001≤n≤0.017, and 0.95≤k≤1.10.)

According to the present disclosure, a rare earth aluminate phosphor enabling a light emitting device to achieve higher emission intensity and higher emission efficiency, a light emitting device, and a projector can be provided.

### BRIEF DESCRIPTION OF THE DRAWINGS

FIG. 1 is a line drawing of a first rare earth aluminate phosphor particle in a SEM image.

FIG. 2 is a line drawing of the first rare earth aluminate phosphor particle and second rare earth aluminate phosphor parts in a SEM image obtained by irradiating the rare earth aluminate phosphor shown in FIG. 1 with accelerated electrons in accordance with cathodoluminescence excitation spectroscopy.

FIG. 3 is an image of a cross section of the rare earth aluminate phosphor in FIG. 2 taken along line II-II′.

FIG. 4 is a schematic configuration diagram of an example of light emitting device.

FIG. 5 is a schematic cross-sectional view showing one example of the configuration of a wavelength conversion member.

FIG. 6 is a schematic perspective view of the example of the configuration of the wavelength conversion member.

FIG. 7 is a schematic plan view of the example of the configuration of the wavelength conversion member.

FIG. 8 is a schematic configuration diagram of a projector.

FIG. 9 is a SEM image of the rare earth aluminate phosphor of Example 4.

FIG. 10 is a binarized Ga elemental map image of the SEM micrograph of the rare earth aluminate phosphor of Example 4.

FIG. 11 is a binarized Ga elemental map image of a SEM micrograph of the rare earth aluminate phosphor of Example 5.

FIG. 12 is a binarized Ga elemental map image of a SEM micrograph of the rare earth aluminate phosphor of Comparative Example 5.

### DETAILED DESCRIPTION

A rare earth aluminate phosphor and a light emitting device of the present disclosure will be explained below. The embodiments described below are examples provided to give shape to the technical ideas of the present invention, and the present invention is not limited to the rare earth aluminate phosphors and light emitting devices described below. With respect to visible light, the relationship between color name and chromaticity coordinates, the relationship between wavelength range and color name of single color light, and the like are in accordance with JIS Z8110.

A rare earth aluminate phosphor includes,
a first rare earth aluminate phosphor particle having a composition represented by the formula (I) below,
a second rare earth aluminate phosphor part having a composition with a Ga molar ratio higher than a Ga molar ratio in one mole of the composition represented by the formula (I), the second rare earth aluminate phosphor part being present on a surface of first rare earth aluminate phosphor particle, wherein
a Ga content measured by X-ray fluorescence spectrometry in the rare earth aluminate phosphor is 0.5% by mass or higher and lower than 3.0% by mass when a total of at least one element R¹ selected from the group consisting of Y, La, Lu, Gd, and Tb; Ce; Al; and at least one element M¹ selected from the group consisting of Ga and Sc is 100% by mass.

(R¹₁₋ₙCeₙ)₃(Al₁₋ₘM¹ₘ)₅ₖO₁₂ (I)

(In the formula (I), R¹ is at least one element selected from the group consisting of Y, La, Lu, Gd, and Tb, M¹ is at least one element selected from the group consisting of Ga and Sc, and m, n, and k respectively satisfy 0≤m≤0.012, 0.001≤n≤0.017, and 0.95≤k≤1.10.)

A rare earth aluminate phosphor has, on the surface of a first rare earth aluminate phosphor particle having a composition represented by the formula (I) below, a second rare earth aluminate phosphor part having a composition with a higher Ga molar ratio than the Ga molar ratio in one mole of the composition represented by the formula (I), and a Ga content of 1.0% by mass or higher and lower than 3.0% by mass measured by X-ray fluorescence spectrometry when the total of at least one element R¹ selected from the group consisting of Y, La, Lu, Gd, and Tb, Ce, Al, and at least one element M¹ selected from Ga and Sc is 100% by mass.

(R¹₁₋ₙCeₙ)₃(Al₁₋ₘM¹ₘ)₅ₖO₁₂ (I)

(In the formula (I), R¹ is at least one element selected from the group consisting of Y, La, Lu, Gd, and Tb, M¹ is at least one element selected from the group consisting of Ga and Sc, and m, n, and k respectively satisfy 0≤m≤0.012, 0.001≤n≤0.017, and 0.95≤k≤1.10.)

A rare earth aluminate phosphor has, on the surface of a first rare earth aluminate phosphor particle having a composition represented by the formula (I), a second rare earth aluminate phosphor part having a composition with a higher Ga molar ratio than the Ga molar ratio in one mole of the composition represented by the formula (I). In the present specification, one that has “a first rare earth aluminate phosphor particle” having a composition represented by the formula (I) and “a second rare earth aluminate phosphor part” having a composition with a higher Ga molar ratio than the Ga molar ratio in one mole of the composition represented by the formula (I) on the surface of the first rare earth aluminate phosphor particle is also referred to as a “rare earth aluminate phosphor.” In a rare earth aluminate phosphor, the structural crystal defects of the surface of a first rare earth aluminate phosphor particle are compensated for by Ga of a second rare earth aluminate phosphor part. A rare earth aluminate phosphor having a second rare earth aluminate phosphor part compensating for the structural crystal defects of the surface of a first rare earth aluminate phosphor particle can emit light having higher emission intensity and higher emission efficiency when irradiated with the light from a light source. A light emitting device using a rare earth aluminate phosphor having a second rare earth aluminate phosphor part that compensates for the structural crystal defects of the surface of a first rare earth aluminate phosphor particle can have high emission efficiency as the emission intensity of the rare earth aluminate phosphor is enhanced.

A second rare earth aluminate phosphor part has a shape that slightly projects from the surface of a first rare earth aluminate phosphor particle because the composition of the second rare earth aluminate phosphor part has a higher Ga content than the composition of the first rare earth aluminate phosphor particle, resulting in the presence of a protrusion and an recession created by the second rare earth aluminate phosphor part on the surface of the first rare earth aluminate phosphor particle. Because the protrusion and recession created by the second rare earth aluminate phosphor part are present on the surface of the first rare earth aluminate phosphor particle, the rare earth aluminate phosphor can facilitate scattering of light irradiated by a light source. The rare earth aluminate phosphor which allows the second rare earth aluminate phosphor part on the surface of the first rare earth aluminate phosphor particle to scatter light has improved absorption of the light from the light source and higher wavelength conversion efficiency caused by the rare earth aluminate phosphor, and can emit light having higher emission intensity and higher emission efficiency. A light emitting device employing the rare earth aluminate phosphor that has a second rare earth aluminate phosphor part on the surface of the first rare earth aluminate phosphor particle can have high emission efficiency, as the rare earth aluminate phosphor has enhanced emission intensity.

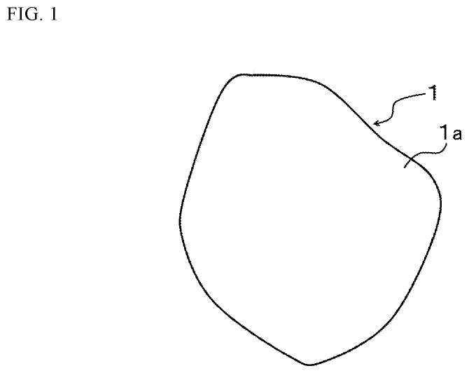

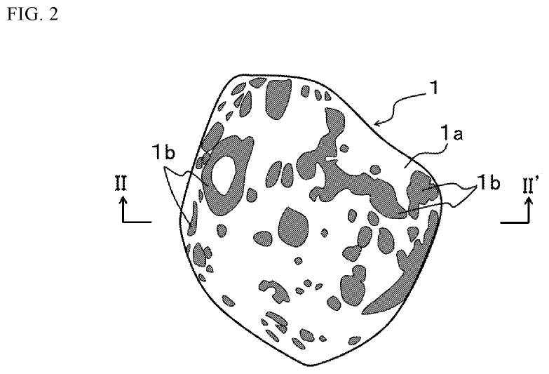

Whether or not a second rare earth aluminate phosphor part having a higher Ga molar ratio than the Ga molar ratio in one mole of the composition of the first rare earth aluminate phosphor particle is present on the surface of the first rare earth aluminate phosphor particle can be confirmed by capturing a SEM image of the rare earth aluminate phosphor by using a scanning electron microscope (SEM), followed by doing a Ga analysis or Ga elemental mapping for the same rare earth aluminate phosphor by using an energy dispersive X-ray fluorescence spectrometer (EDX). Whether or not a second rare earth aluminate phosphor part having a higher Ga molar ratio than the Ga molar ratio in one mole of the composition of the first rare earth aluminate phosphor particle is present on the surface of the first rare earth aluminate phosphor particle can alternatively be confirmed by capturing a SEM image of the rare earth aluminate phosphor by using a SEM, followed by obtaining a SEM image (CL image) by irradiating the same rare earth aluminate phosphor with accelerated electrons in accordance with the cathodoluminescence (CL) method. FIG. 1 is a line drawing of a first rare earth aluminate phosphor particle in an image of the rare earth aluminate phosphor captured by using a SEM. FIG. 2 is a line drawing of the first rare earth aluminate phosphor particle and second rare earth aluminate phosphor parts present on the surface of the first rare earth aluminate phosphor particle in a SEM image (CL image) obtained by irradiating the rare earth aluminate phosphor with accelerated electrons in accordance with to the CL method. As shown in FIG. 2, the surface of the first rare earth aluminate phosphor particle 1a of the rare earth aluminate phosphor 1 irradiated with accelerated electrons by the CL method resulted in a color change in the second rare earth aluminate phosphor parts 1b which had higher Ga molar ratio, confirming the presence of the second rare earth aluminate phosphor parts 1b having a higher Ga molar ratio on the surface of the first rare earth aluminate phosphor particle 1a where the color has not changed.

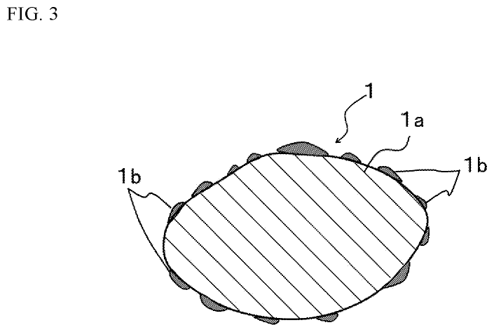

FIG. 3 is an image of a cross section of the rare earth aluminate phosphor 1 shown in FIG. 2 taken along line II-II′. The rare earth aluminate phosphor 1 has second rare earth aluminate phosphor parts 1b having a higher Ga molar ratio than the Ga molar ratio in one mole of the composition represented by the formula (I) on the surface of the first rare earth aluminate phosphor particle 1a having a composition represented by the formula (I). The second rare earth aluminate phosphor parts 1b are present on and slightly projecting from the surface of the first rare earth aluminate phosphor particle 1a. The rare earth aluminate phosphor 1 has on the surface of the first rare earth aluminate phosphor particle 1a fine protrusions and recessions created by the second rare earth aluminate phosphor parts 1b present on the surface of the first rare earth aluminate phosphor particle 1a.

A rare earth aluminate phosphor preferably has multiple second rare earth aluminate phosphor parts on the surface of a first rare earth aluminate phosphor particle. The rare earth aluminate phosphor including multiple second rare earth aluminate phosphor parts on the surface of a first rare earth aluminate phosphor particle, i.e., including multiple second rare earth aluminate phosphor parts compensating for the structural crystal defects of the surface of the first rare earth aluminate phosphor particle, can emit light with higher emission intensity and higher emission efficiency when irradiated with light from a light source. A light emitting device using a rare earth aluminate phosphor which includes multiple second rare earth aluminate phosphor parts compensating for the structural crystal defects of the surface of a first rare earth aluminate phosphor particle can have even higher emission efficiency as the rare earth aluminate phosphor has higher emission intensity.

A rare earth aluminate phosphor including multiple second rare earth aluminate phosphor parts on the surface of a first rare earth aluminate phosphor particle has fine protrusions and recessions created by the multiple second rare earth aluminate phosphor parts. Because of presence of the fine protrusions and recessions created by the second rare earth aluminate phosphor parts on the surface of the first rare earth aluminate phosphor particle, the rare earth aluminate phosphor can facilitate scattering of the light from a light source to improve the absorption of the light from the light source and the wavelength conversion efficiency caused by the rare earth aluminate phosphor particles, and can emit light having higher emission intensity and higher emission efficiency. A light emitting device using a rare earth aluminate phosphor including multiple second rare earth aluminate phosphor parts on the surface of a first rare earth aluminate phosphor particle can have higher emission efficiency as the rare earth aluminate phosphor has higher emission intensity.

A rare earth aluminate phosphor preferably includes multiple sporadically located second rare earth aluminate phosphor parts on the surface of a first rare earth aluminate phosphor particle. The rare earth aluminate phosphor including multiple sporadically located second rare earth aluminate phosphor parts on the surface of a first rare earth aluminate phosphor particle, i.e., including multiple sporadically located second rare earth aluminate phosphor parts that compensate for the structural crystal defects of the surface of the first rare earth aluminate phosphor particle, can emit light having higher emission intensity and higher emission efficiency when irradiated with light from a light source. A light emitting device using a rare earth aluminate phosphor including multiple sporadically located second rare earth aluminate phosphor parts, compensating for the structural crystal defects, on the surface of the first rare earth aluminate phosphor particle can have higher emission efficiency as the emission intensity of the rare earth aluminate phosphor is further enhanced.

A rare earth aluminate phosphor including multiple sporadically located second rare earth aluminate phosphor parts on the surface of a first rare earth aluminate phosphor particle has finer protrusions and recessions because the second rare earth aluminate phosphor parts are sporadically located. Because of finer protrusions and recessions created by the second rare earth aluminate phosphor parts sporadically located on the surface of the first rare earth aluminate phosphor particle, the rare earth aluminate phosphor can facilitate scattering of the light from a light source to improve the absorption of the light from a light source and the wavelength conversion efficiency caused by the rare earth aluminate phosphor particles, thereby emitting light with higher emission intensity and higher emission efficiency. A light emitting device employing a rare earth aluminate phosphor including sporadically located second rare earth aluminate phosphor parts on the surface of the first rare earth aluminate phosphor particle can have higher emission efficiency as the rare earth aluminate phosphor has higher emission intensity.

A rare earth aluminate phosphor has a first rare earth aluminate phosphor particle having a composition represented by the formula (I) and a second rare earth aluminate phosphor part having a composition with a higher Ga molar ratio than the Ga molar ratio in one mole of the composition represented by the formula (I), and a Ga content of 0.5% by mass or higher and lower than 3.0% by mass, or 1.0% by mass or higher and lower than 3.0% by mass, measured by X-ray fluorescence spectrometry when the total of at least one element R¹ selected from the group consisting of Y, La, Lu, Gd, and Tb; Ce; Al; and at least one element M¹ selected from the group consisting of Ga and Sc is 100% by mass. As long as the Ga content measured by X-ray fluorescence spectrometry is 0.5% by mass or higher and lower than 3.0% by mass, or 1.0% by mass or higher and lower than 3.0% by mass, when the total of element R¹, Ce, Al, and element M¹ is 100% by mass, the structural crystal defects of the first rare earth aluminate phosphor particle having a composition represented by the formula (I) are compensated for by the second rare earth aluminate phosphor part having a higher Ga molar ratio than the Ga molar ratio in one mole of the composition represented by the formula (I) and the crystal structure of the rare earth aluminate phosphor stabilized. The rare earth aluminate phosphor thus can emit light having higher emission intensity and higher emission efficiency when irradiated with the light from a light source. As long as the Ga content measured by X-ray fluorescence spectrometry is 0.5% by mass or higher and lower than 3.0% by mass, or 1.0% by mass or higher and lower than 3.0% by mass, when the total of element R¹, Ce, Al, and element M¹ is 100% by mass, protrusions and recessions created by the second rare earth aluminate phosphor parts are present on the surface of the first rare earth aluminate phosphor particle. The rare earth aluminate phosphor thus can emit light having higher emission intensity and higher emission efficiency when irradiated with the light from a light source. If the Ga content measured by X-ray fluorescence spectrometry is lower than 0.5% by mass when the total of element R¹, Ce, Al, and element M¹ is 100% by mass, the structural crystal defects of a first rare earth aluminate phosphor particle might not be sufficiently compensated for by the second rare earth aluminate phosphor part and the emission intensity of the rare earth aluminate phosphor may not be improved. This can make the output intensity of a light emitting device using the rare earth aluminate phosphor less apt to change, the light extraction efficiency may not be improved. If the Ga content measured by X-ray fluorescence spectrometry is 3.0% by mass or higher when the total of element R¹, Ce, Al, and element M¹ is 100% by mass, too many second rare earth aluminate phosphor parts might result on the surface of the first rare earth aluminate phosphor particle, the output intensity of a light emitting device employing the rare earth aluminate phosphor might be reduced and the light extraction efficiency might fail to improve. The Ga content of a rare earth aluminate phosphor measured by X-ray fluorescence spectrometry is preferably in a range of 0.5% by mass to 2.9% by mass, more preferably 0.6% by mass to 2.9% by mass, and may be in a range of 0.9% by mass to 2.9% by mass, 1.0% by mass to 2.9% by mass, 1.1% by mass to 2.8% by mass, or 1.2% by mass to 2.5% by mass when the total of element R¹, Ce, Al, and element M¹ is 100% by mass.

Elements can be measured according to X-ray fluorescence spectrometry (XRF) by using an X-ray fluorescence spectrometer and calibration curves. A calibration curve establishing the correlation between the concentrations of a standard sample of an element to be analyzed and the X-ray intensities at the concentrations of the standard sample is prepared by linear approximation. Based on the calibration curves prepared by using standard samples, concentrations of the elements in a sample can be found from the X-ray intensities of the elements in the sample measured by using an X-ray fluorescence spectrometer. For the standard samples, oxides of the elements can be used. For the element R¹, Ce, Al, and the element M¹ measured by X-ray fluorescence spectrometry, the values in terms of oxides sum to the total, 100% by mass. The concentrations of the elements R¹, Ce, Al, M¹, and Ga in terms of oxides can be obtained by converting the peak intensities of the respective Kα lines of the elements into concentrations based on the calibration curves of the elements. Based on the resultant concentrations of the elements, the Ga content (% by mass) can be obtained by using the sum of the concentrations of elements R¹, Ce, Al, and element M¹ as 100% by mass. In the case in which element M¹ includes Sc and Ga, the concentration of the element M¹ is the sum of the concentrations of Sc and Ga. In the case in which element M¹ is Ga, the concentration of the element M¹ is the concentration of Ga. Calibration curves may be prepared in accordance with JIS Z8461. In the case in which element R¹ includes two or more elements, the concentration of the element R¹ is the sum of concentrations of the two or more elements included in the element R¹.

Here, a first pixel total count p×1 is determined by calculating the total number of pixels of one or more first rare earth aluminate phosphor particles in an image captured by a scanning electron microscope (SEM). Also, a second total pixel count p×2 is determined by calculating the total number of pixels of Ga in the second rare earth aluminate phosphor parts on the surfaces of the first rare earth aluminate phosphor particles in an image obtained by an energy dispersive X-ray fluorescence spectrometer (EDX). A rare earth aluminate phosphor preferably has a pixel percentage obtained by dividing the second total pixel count p×2 by the first total pixel count p×1 (p×2/p×1×100) is in a range of 5.0% to 80.0%. The pixel percentage might be occasionally expressed as “p×2/p×1” or “pixel percentage (p×2/p×1).” As long as the pixel percentage (p×2/p×1) of a rare earth aluminate phosphor is in the range of 5.0% to 80.0%, the structural crystal defects of the first rare earth aluminate phosphor particles can be compensated for by Ga in the second rare earth aluminate phosphor parts, and fine protrusions and recessions created by the second rare earth aluminate phosphor parts are present on the surfaces of the first rare earth aluminate phosphor particles. This allows the rare earth aluminate phosphor to emit light having higher emission intensity and higher emission efficiency when irradiated with light from a light source. The pixel percentage (p×2/p×1) of a rare earth aluminate phosphor is more preferably in a range of 8.0% to 78.0%, even more preferably in a range of 10.0% to 77.0%.

A rare earth aluminate phosphor preferably has, on the surface of a first rare earth aluminate phosphor particle having a composition represented by the formula (I) below, a second rare earth aluminate phosphor part having a composition with a higher Ga molar ratio than the Ga molar ratio in one mole of the composition represented by the formula (I), a Ga content of 0.5% by mass or higher and lower than 3.0% by mass measured by X-ray fluorescence spectrometry when the total of at least one element R¹ selected from the group consisting of Y, La, Lu, Gd, and Tb, Ce, Al, and at least one element M¹ selected from the group of Ga and Sc is 100% by mass, and a pixel percentage (p×2/p×1×100) in a range of 5.0% to 80.0% obtained by calculating a first pixel total count, which is the total number of pixels of one or more first rare earth aluminate phosphor particles in an image captured by a scanning electron microscope (SEM), calculating a second total pixel count, which is the total number of pixels of Ga in the second rare earth aluminate phosphor parts on the surfaces of the first rare earth aluminate phosphor particles in an image obtained by an energy dispersive X-ray fluorescence spectrometer (EDX), and dividing the second total pixel count by the first total pixel count.

(R¹₁₋ₙCeₙ)₃(Al₁₋ₘM¹ₘ)₅ₖO₁₂ (I)

(In the formula (I), R¹ is at least one element selected from the group consisting of Y, La, Lu, Gd, and Tb, M¹ is at least one element selected from the group consisting of Ga and Sc, and m, n, and k respectively satisfy 0≤m≤0.012, 0.001≤n≤0.017, and 0.95≤k≤1.10.)

As long as the pixel percentage (p×2/p×1) of a rare earth aluminate phosphor is in the range of 5.0% to 80.0%, the structural crystal defects of the first rare earth aluminate phosphor particles having a composition represented by the formula (I) can be compensated for by Ga in the second rare earth aluminate phosphor parts having a composition with a higher Ga molar ratio than the Ga molar ratio in one mole of the composition represented by the formula (I), and fine protrusions and recessions created by the second rare earth aluminate phosphor parts are present on the surfaces of the first rare earth aluminate phosphor particles. This allows the rare earth aluminate phosphor to emit light having higher emission intensity and higher emission efficiency when irradiated with light from a light source.

A rare earth aluminate phosphor preferably has, on the surface of a first rare earth aluminate phosphor particle having the composition represented by the formula (I) below, a second rare earth aluminate phosphor part having a composition with a higher Ga molar ratio than the Ga molar ratio in one mole of the composition represented by the formula (I), a Ga content of 1.0% by mass or higher and lower than 3.0% by mass measured by X-ray fluorescence spectrometry when the total of at least one element R¹ selected from the group consisting of Y, La, Lu, Gd, and Tb, Ce, Al, and at least one element M¹ selected from the group of Ga and Sc is 100% by mass, and a pixel percentage (p×2/p×1×100) in a range of 5.0% to 80.0% obtained by calculating a first pixel total count, which is the total number of pixels of one or more first rare earth aluminate phosphor particles in an image captured by a scanning electron microscope (SEM), calculating a second total pixel count, which is the total number of pixels of Ga in the second rare earth aluminate phosphor parts on the surfaces of the first rare earth aluminate phosphor particles in an image obtained by an energy dispersive X-ray fluorescence spectrometer (EDX), and dividing the second total pixel count by the first total pixel count.

(R¹₁₋ₙCeₙ)₃(Al₁₋ₘM¹ₘ)₅ₖO₁₂ (I)

(In the formula (I), R¹ is at least one element selected from the group consisting of Y, La, Lu, Gd, and Tb, M¹ is at least one element selected from the group consisting of Ga and Sc, and m, n, and k respectively satisfy 0≤m≤0.012, 0.001≤n≤0.017, and 0.95≤k≤1.10.)

As long as the pixel percentage (p×2/p×1) of a rare earth aluminate phosphor is in the range of 5.0% to 80.0%, the structural crystal defects of the first rare earth aluminate phosphor particles having a composition represented by the formula (I) can be compensated for by Ga in the second rare earth aluminate phosphor parts having a composition with a higher Ga molar ratio than the Ga molar ratio in one mole of the composition represented by the formula (I), and fine protrusions and recessions created by the second rare earth aluminate phosphor parts are present on the surfaces of the first rare earth aluminate phosphor particles. This allows the rare earth aluminate phosphor to emit light having higher emission intensity and higher emission efficiency when irradiated with the light from a light source.

A rare earth aluminate phosphor preferably has a composition represented by the formula (II) below when analyzed after dissolving the first rare earth aluminate phosphor particles and the second rare earth aluminate phosphor parts entirely.

(R¹₁₋ₙCeₙ)₃(Al_{1-p-q}GaₚSc_{q})₅ₖO₁₂ (II)

(In the formula (II), R¹ is at least one element selected from the group consisting of Y, La, Lu, Gd, and Tb, and n, p, q, and k respectively satisfy 0.001≤n≤0.017, 0.009<p<0.034, 0≤q≤0.012, and 0.95≤k≤1.10.)

Because a second rare earth aluminate phosphor part having a higher Ga molar ratio than the Ga molar ratio in one mole of the composition represented by the formula (I) is located partially on the surface of a first rare earth aluminate phosphor particle having the composition represented by the formula (I), it is difficult to analyze the composition of only the second rare earth aluminate phosphor part. As the composition of the rare earth aluminate phosphor analyzed after dissolving the first rare earth aluminate phosphor particles and the second rare earth aluminate phosphor parts entirely has a larger Ga molar ratio than the Ga molar ratio in the composition of the first rare earth aluminate phosphor particles represented by the formula (I), the composition of the second rare earth aluminate phosphor parts is understood to have a larger Ga molar ratio than the Ga molar ratio of the composition represented by the formula (I).

In the composition of a rare earth aluminate phosphor represented by the formula (II), which is the composition analyzed after dissolving the first rare earth aluminate phosphor particles and the second rare earth aluminate phosphor parts entirely, variable p in the product of variable p, 5, and variable k representing the Ga molar ratio is higher than 0.009 and lower than 0.034 (0.009<p<0.034), which may be 0.010 or higher and lower than 0.034 (0.010≤p<0.034), 0.010 or higher and 0.030 or lower (0.010≤p≤0.030), higher than 0.012 and lower than 0.034 (0.012<p<0.034), 0.013 or higher and 0.033 or lower (0.01 3≤p≤0.033), 0.014 or higher and 0.032 or lower (0.014≤p≤0.032), 0.015 or higher and 0.031 or lower (0.015≤p<0.031), or 0.016 or higher and 0.030 or lower (0.016≤p≤0.030). As long as variable p in the product of variable p, 5, and variable k representing the Ga molar ratio is higher than 0.009 and lower than 0.034 (0.009<p<0.034) in the composition represented by the formula (II), which is the composition analyzed after dissolving the first rare earth aluminate phosphor particles and the second rare earth aluminate phosphor parts entirely, the structural crystal defects of the surfaces of the first rare earth aluminate phosphor particles having a composition represented by the formula (I) are compensated for by the second rare earth aluminate phosphor parts having a composition with a higher Ga molar ratio than the Ga molar ratio in one mole of the composition represented by the formula (I), and protrusions and recessions created by the second rare earth aluminate phosphor parts are present on the surfaces of the first rare earth aluminate phosphor particles. The rare earth aluminate phosphor can thus emit light having higher emission intensity and higher emission efficiency when irradiated with light from a light source.

A rare earth aluminate phosphor preferably includes Y as a prerequisite for R¹ in the formula (I), and has a Ga content ratio of 1.0 mass % or higher and lower than 3.0 mass % when the total of element R¹, Ce, Al, and element M¹ is 100% by mass.

It is presumed for a rare earth aluminate phosphor that the amount of second rare earth aluminate phosphor parts having a composition with a higher Ga molar ratio than the Ga molar ratio in one mole of the composition represented by the formula (I) formed is different depending on the element that constitutes the host crystal of a rare earth aluminate phosphor. In the case in which R¹ in the composition represented by the formula (I) includes Y as a prerequisite, as long as the Ga content measured by X-ray fluorescence spectrometry is 1.0% by mass or higher and lower than 3.0% by mass when the total of the element R¹, Ce, Al, and the element M¹ is 100% by mass, protrusions and recessions created by second rare earth aluminate phosphor parts are present on the surfaces of first rare earth aluminate phosphor particles. The rare earth aluminate phosphor can thus emit light having higher emission intensity and higher emission efficiency when irradiated with light from a light source. When the rare earth aluminate phosphor has multiple second rare earth aluminate phosphor parts on the surface of a first rare earth aluminate phosphor particle, it has fine protrusions and recessions created by the second rare earth aluminate phosphor parts. This allows for facilitated scattering of the light from a light source, thereby improving the absorption of the light from a light source by and the wavelength conversion efficiency of the rare earth aluminate phosphor particles. The rare earth aluminate phosphor can thus emit light having higher emission intensity and higher emission efficiency. The rare earth aluminate phosphor, in the case in which R¹ in the composition represented by the formula (I) includes Y as a prerequisite, more preferably has a Ga content of 1.0% by mass to 2.5% by mass when the total of the element R¹, Ce, Al, and the element M¹ is 100% by mass measured by X-ray fluorescence spectrometry. The Ga content may be 1.1% by mass to 2.0% by mass, or 1.4% by mass to 2.0% by mass.

A rare earth aluminate phosphor preferably includes Y as a prerequisite for R¹ in the formula (II) while p satisfies 0.012<p<0.034. The rare earth aluminate phosphor preferably includes Y as a prerequisite for R¹ in the composition represented by the formula (II) analyzed after dissolving the first rare earth aluminate phosphor particles and the second rare earth aluminate phosphor parts entirely, in which variable p in the product of variable p, 5, and variable k representing the Ga molar ratio is preferably higher than 0.012 and lower than 0.034 (0.012<p<0.034), more preferably 0.013 or higher and 0.033 or lower (0.013≤p≤0.033), even more preferably 0.014 or higher and 0.032 or lower (0.014≤p≤0.032), even more preferably 0.015 or higher and 0.031 or lower (0.015≤p≤0.031), particularly preferably 0.016 or higher and 0.030 or lower (0.016≤p≤0.030). As long as R¹ in the composition represented by the formula (II), which is the composition analyzed after dissolving the first rare earth aluminate phosphor particles and the second rare earth aluminate phosphor parts entirely, includes Y as a prerequisite and variable p in the product of variable p, 5, and variable k representing the Ga molar ratio is higher than 0.012 and lower than 0.034 (0.012<p<0.034), the structural crystal defects of the first rare earth aluminate phosphor particles having a composition represented by the formula (I) are compensated for by Ga in the second rare earth aluminate phosphor parts having a composition with a higher Ga molar ratio than the Ga molar ratio in one mole of the composition represented by the formula (I), and protrusions and recessions created by the second rare earth aluminate phosphor parts are present on the surfaces of the first rare earth aluminate phosphor particles. This allows the rare earth aluminate phosphor to emit light with higher emission intensity and higher emission efficiency when irradiated with light from a light source. When the rare earth aluminate phosphor has multiple second rare earth aluminate phosphor parts on the surface of a first rare earth aluminate phosphor particle, it has fine protrusions and recessions created by the second rare earth aluminate phosphor parts. This allows for facilitated scattering of the light from a light source, thereby improving the absorption of the light from a light source by and the wavelength conversion efficiency of the rare earth aluminate phosphor particles. The rare earth aluminate phosphor can thus emit light having higher intensity and higher emission efficiency.

The rare earth aluminate phosphor may include a trace amount of an element selected from the group consisting of La, Lu, Gd, and Tb in the raw materials for forming the rare earth aluminate phosphor in the case in which R¹ in the formula (II) includes Y as a prerequisite. As to the rare earth aluminate phosphor in the case in which R¹ in the formula (II) includes Y as a prerequisite, and R¹ includes a trace amount of an element selected from the group consisting of La, Lu, Gd, and Tb, which excludes Y, 99% of the total molar amount of R¹ or higher is preferably Y.

A rare earth aluminate phosphor preferably includes Lu as a prerequisite for R¹ in the formula (I), and has a Ga content of 0.5% by mass or higher and lower than 3.0 mass % when the total of element R¹, Ce, Al, and element M¹ is 100% by mass.

It is presumed for a rare earth aluminate phosphor that the content ratio of Ga which demonstrates the effect of increasing the emission intensity measured by X-ray fluorescence spectrometry when the total of element R¹, Ce, Al, and element M¹ is 100% by mass is different depending on the element that constitutes the host crystal of a first rare earth aluminate phosphor particle. The reason is unclear as to why the Ga content ratio which demonstrates the effect of increasing the emission intensity measured by X-ray fluorescence spectrometry when the sum of element R¹, Ce, Al, and element M¹ is 100% by mass differs depending on the element constituting the host crystal of the first rare earth aluminate phosphor particle. It is presumed that, when the mass of the element constituting the host crystal of the first rare earth aluminate phosphor particle is larger, the large mass first rare earth aluminate phosphor particles act as caps, making the volatilized gas less apt to escape when only the compound containing Ga, together with the first rare earth aluminate phosphor particles, is subjected to a second heat treatment in the method of manufacturing a rare earth aluminate phosphor described later. It is presumed that, when the mass of the element constituting the host crystals of the first rare earth aluminate phosphor particles is larger and the volatilized gas is less apt to escape because the first rare earth aluminate phosphor particles act as caps during the second heat treatment in the method of manufacturing a rare earth aluminate phosphor described later, the second rare earth aluminate phosphor parts are readily formed on the surfaces of the first rare earth aluminate phosphor particles. Thus, fine protrusions and recessions are created by the second rare earth aluminate phosphor parts on the surfaces of the first rare earth aluminate phosphor particles even if the Ga content measured by X-ray fluorescence spectrometry is 1.0% by mass or lower when the total of element R¹, Ce, Al, and element M¹ is 100% by mass. In the case in which R¹ in the composition represented by the formula (I) includes Lu as a prerequisite, as long as the Ga content measured by X-ray fluorescence spectrometry is 0.5% by mass or higher and lower than 3.0% by mass when the total of the element R¹, Ce, Al, and the element M¹ is 100% by mass, protrusions and recessions created by second rare earth aluminate phosphor parts are present on the surfaces of first rare earth aluminate phosphor particles. The rare earth aluminate phosphor can thus emit light having higher emission intensity and higher emission efficiency when irradiated with light from a light source. When the rare earth aluminate phosphor has multiple second rare earth aluminate phosphor parts on the surface of a first rare earth aluminate phosphor particle, it has fine protrusions and recessions created by the second rare earth aluminate phosphor parts. This allows for facilitated scattering of the light from a light source, thereby improving the absorption of the light from a light source by and the wavelength conversion efficiency of the rare earth aluminate phosphor particles. The rare earth aluminate phosphor can thus emit light having higher emission intensity and higher emission efficiency. The rare earth aluminate phosphor, in the case in which R¹ in the composition represented by the formula (I) includes Lu as a prerequisite, more preferably has a Ga content of 0.5% by mass to 2.5% by mass, even more preferably 0.6% by mass to 2.0% by mass when the total of the element R¹, Ce, Al, and the element M¹ is 100% by mass measured by X-ray fluorescence spectrometry. The Ga content may be 0.8% by mass to 1.5% by mass.

A rare earth aluminate phosphor preferably includes Lu as a prerequisite for R¹ in the formula (II) while p satisfies 0.010≤p<0.034.

The rare earth aluminate phosphor preferably includes Lu as a prerequisite for R¹ in the composition represented by the formula (II), which is the composition analyzed after dissolving the first rare earth aluminate phosphor particles and the second rare earth aluminate phosphor parts entirely, in which the variable p in the product of variable p, 5, and variable k representing the Ga molar ratio is preferably 0.010 or higher and lower than 0.034 (0.010≤p<0.034), more preferably 0.011 or higher and 0.030 or lower (0.011≤p≤0.030), even more preferably 0.012 or higher and 0.025 or lower (0.012≤p≤0.025), even more preferably 0.013 or higher and 0.020 or lower (0.013≤p≤0.020), particularly preferably 0.014 or higher and 0.019 or lower (0.014≤p≤0.019). As long as R¹ in the composition represented by the formula (II), which is the composition analyzed after dissolving the first rare earth aluminate phosphor particles and the second rare earth aluminate phosphor parts entirely, includes Lu as a prerequisite and variable p in the product of variable p, 5, and variable k representing the Ga molar ratio is 0.010 or higher and lower than 0.034 (0.010≤p<0.034), the structural crystal defects of the first rare earth aluminate phosphor particles having a composition represented by the formula (I) are compensated for by Ga in the second rare earth aluminate phosphor parts having a composition with a higher Ga molar ratio than the Ga molar ratio in one mole of the composition represented by the formula (I), and protrusions and recessions created by the second rare earth aluminate phosphor parts are present on the surfaces of the first rare earth aluminate phosphor particles. This allows the rare earth aluminate phosphor to emit light with higher emission intensity and higher emission efficiency when irradiated with light from a light source. When the rare earth aluminate phosphor has multiple second rare earth aluminate phosphor parts on the surface of a first rare earth aluminate phosphor particle, it has fine protrusions and recessions created by the second rare earth aluminate phosphor parts. This allows for facilitated scattering of the light from a light source, thereby improving the absorption of the light from a light source by and the wavelength conversion efficiency of the rare earth aluminate phosphor particles. The rare earth aluminate phosphor can thus emit light having higher intensity and higher emission efficiency.

The rare earth aluminate phosphor may include a trace amount of an element selected from the group consisting of Y, La, Gd, and Tb in the raw materials for forming the rare earth aluminate phosphor in the case in which R¹ in the formula (II) includes Lu as a prerequisite. As to the rare earth aluminate phosphor in the case in which R¹ in the formula (II) includes Lu as a prerequisite, and R¹ includes a trace amount of an element selected from the group consisting of Y, La, Gd, and Tb, which excludes Lu, 99% of the total molar amount of R¹ or higher is preferably Lu.

In the composition of a rare earth aluminate phosphor represented by the formula (II), which is the composition analyzed after dissolving the first rare earth aluminate phosphor particles and the second rare earth aluminate phosphor parts entirely, variable k in the product of variable p, 5, and variable k representing the Ga molar ratio is preferably 0.95 to 1.10 (0.95≤k≤1.10), more preferably 0.97 to 1.05 (0.97≤k≤1.05), even more preferably 0.98 to 1.02 (0.98≤k≤1.02), even more preferably 0.99 to 1.01 (0.99≤k≤1.01). As long as variable k in the product of variable p, 5, and variable k representing the Ga molar ratio is 0.097 to 1.10 (0.095≤k≤1.10) in the composition represented by the formula (II), which is the composition analyzed after dissolving the first rare earth aluminate phosphor particles and the second rare earth aluminate phosphor parts entirely, the structural crystal defects of the surfaces of the first rare earth aluminate phosphor particles having a composition represented by the formula (I) are compensated for by the second rare earth aluminate phosphor parts having a composition with a higher Ga molar ratio than the Ga molar ratio in one mole of the composition represented by the formula (I), and protrusions and recessions created by the second rare earth aluminate phosphor parts are present on the surfaces of the first rare earth aluminate phosphor articles. The rare earth aluminate phosphor can thus emit light having higher emission intensity and higher emission efficiency when irradiated with light from a light source.

The average particle size of a rare earth aluminate phosphor having second rare earth aluminate phosphor parts on the surfaces of the first rare earth aluminate phosphor particles measured by the Fisher Sub-sieve Sizer method (also occasionally referred to as the FSSS method) is preferably in a range of 15 μm to 35 μm, but may be in a range of 20 μm to 34 μm or in a range of 25 μm to 33 μm. As long as the average particle size of a rare earth aluminate phosphor having second rare earth aluminate phosphor parts on the surfaces of first rare earth aluminate phosphor particles is in a range of 15 μm to 35 μm, the rare earth aluminate phosphor absorbs the light from a light source well, has good wavelength conversion efficiency, and can thus emit light having high emission intensity and higher emission efficiency. The FSSS method is a type of air permeability testing methods, and is a method to mainly obtain a particle size of a primary particle by measuring the specific surface area by utilizing airflow resistance. The average particle size measured by the FSSS method is a Fisher Sub-sieve Sizer's number.

The average particle size of the rare earth aluminate phosphor having second rare earth aluminate phosphor parts on the surfaces of first rare earth aluminate phosphor particles might not change from the average particle size of the first rare earth aluminate phosphor particles not having the second rare earth aluminate phosphor parts on the surfaces thereof. The average particle size of the first rare earth aluminate phosphor particles not having second rare earth aluminate phosphor parts on the surfaces thereof measured by the FSSS method is preferably in a range of 14.5 μm to 35 μm, and may be in a range of 15 μm to 35 μm.

A rare earth aluminate phosphor having a second rare earth aluminate phosphor part on the surface of a first rare earth aluminate phosphor particle preferably emits light having a peak wavelength in the 450 nm to 580 nm range in the emission spectrum when irradiated with excitation light having a peak wavelength in the 350 nm to 500 mm range. A rare earth aluminate phosphor even in the case of having a second rare earth aluminate phosphor part on the surface of a first rare earth aluminate phosphor particle can emit light having a desired peak wavelength needed for the first rare earth aluminate phosphor particles.

### Light Emitting Device

A light emitting device includes the rare earth aluminate phosphor described above, and a light emitting element having a peak emission wavelength in a range of 350 nm to 500 nm. The rare earth aluminate phosphor in combination with a light emitting element can configure a light emitting device that emits mixed color light of the light emitted from the light emitting element and the light whose wavelength is converted by the rare earth aluminate phosphor. The peak emission wavelength of the light emitting element may fall within the 350 nm to 500 nm range, 380 nm to 485 nm range, or 390 nm to 480 nm range. The full width at half maximum of the peak emission wavelength of the light emitting element may be, for example, 30 nm or lower. The light emitting element is preferably a semiconductor laser in the case the device is used in a projector, for example. Examples include semiconductor elements. Semiconductor elements may be light emitting diodes or laser diodes. Examples of semiconductor elements include those that use nitride semiconductors (In_{X}Al_{Y}Ga_{1-X-Y}N, 0≤X, 0≤Y, X+Y≤1). Employing a semiconductor light emitting element as the light emitting element can produce a high efficiency light emitting device that has high input-output linearity and is highly stable against mechanical shock.

A light emitting device preferably includes a wavelength conversion member containing the rare earth aluminate phosphor described above, a motor for rotating the wavelength conversion member, and a light emitting element as a light source to irradiate light on the wavelength conversion member. The light emitting device is configured to emit mixed color light combining the light from the light emitting element which is a light source and the light from the wavelength conversion member irradiated with the light from the light emitting element. The light source may include a light emitting element of one type or a combination of two or more types. The light source may include one or plural light emitting elements.

The output from a light source may be 0.5 W/mm² or higher, preferably 5 W/mm² or higher, or may be 10 W/mm² or higher in terms of the optical power density of light irradiated on the wavelength conversion member, for example. The upper limit of the output of a light emitting element may be, for example, 1000 W/mm² or lower, preferably 500 W/mm² or lower, or may be 150 W/mm² or lower.

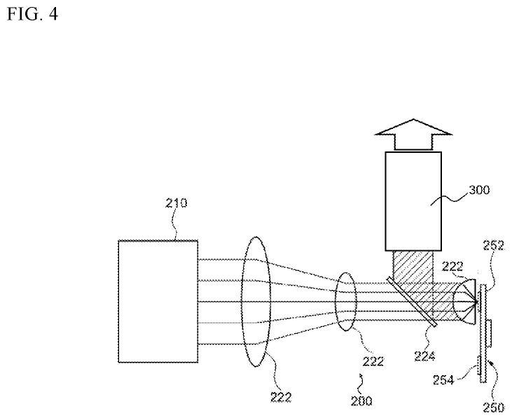

FIG. 4 is a schematic configuration diagram of an example of light emitting device. The light emitting device 200 includes a light source 210 employing a semiconductor laser, a lens 222 for condensing the light from the light source 210 to be irradiated on a wavelength conversion member 250, and a dichroic mirror 224 for reflecting the output light from the wavelength conversion member 250 to direct it to a detector 300. The wavelength conversion member 250 includes a disk-shaped substrate 252 and a wavelength conversion layer 254 which includes a rare earth aluminate phosphor and a binder. The wavelength conversion layer 254 containing the rare earth aluminate phosphor is disposed annularly along the circumference of the substrate 252, for example. The wavelength conversion layer 254 is evaluated, for example, in the form of having the excitation output (W) of the light source 210 employing a semiconductor laser on the horizontal axis and the emission intensity (Iv) of the wavelength conversion layer 254 containing the rare earth aluminate phosphor measured by the detector 300 on the vertical axis. The emission intensity of the light exiting the light emitting device employing the wavelength conversion layer is measured by allowing laser light of 90 W intensity from the semiconductor laser to become incident on the wavelength conversion layer via the dichroic mirror such that the beam diameter of the incident light is 1 mm (q 1 mm). The surface temperature of the wavelength conversion layer 254 can be measured by using an infrared thermographic device.

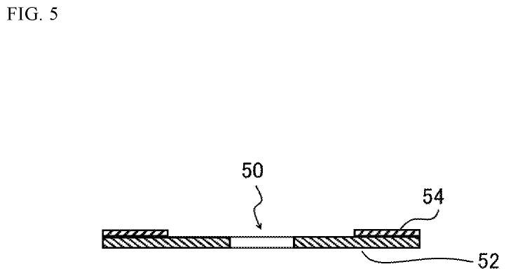

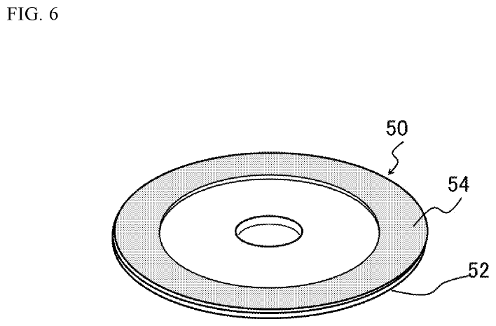

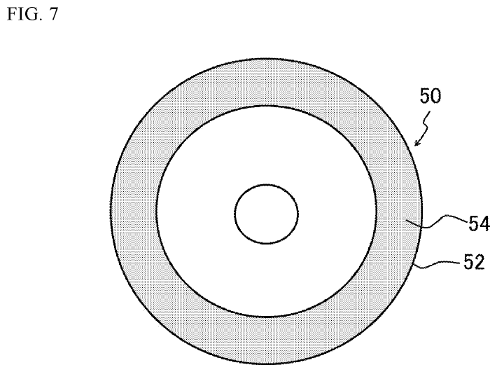

The wavelength conversion member including the rare earth aluminate phosphor described above includes a substrate and a wavelength conversion layer disposed on the substrate. One example of the construction of the wavelength conversion member will be explained here with reference to drawings. FIG. 5 is a schematic cross-sectional view of one example of wavelength conversion member configuration, FIG. 6 is a schematic perspective view of the wavelength conversion member, and FIG. 7 is a schematic plan view of the wavelength conversion member.

The wavelength conversion member 50 has a wavelength conversion layer 54 formed on a substrate 52. In FIG. 5 to FIG. 7, the substrate 52 has a disk shape. The wavelength conversion layer 54 is disposed annularly along the circumference of the substrate 52. The wavelength conversion member 50 absorbs the excitation light from a light source, generates and emits converted light having a different wavelength from that of the excitation light. For example, the wavelength conversion member 50 may be adapted to emit mixed light of blue light and converted light having a different wavelength from that of blue light by absorbing blue light from a light source to be converted by the wavelength conversion layer 54 and reflecting blue light at the same time, or emit only the converted light.

The substrate of the wavelength conversion member is not limited to one having a disk shape, and may have a polygonal sheet shape, for example. The thickness of the substrate may be, for example, 0.1 mm to 1 mm, preferably 0.4 mm to 0.6 mm. The substrate may be a metal member including a metal material, such as aluminum, iron, copper, silver, nickel, or stainless steel. The substrate may be a light transmissive member including a light transmissive material, such as glass, aluminum oxide, or the like. Employing a light transmissive member as the substrate allows the wavelength conversion member to emit light in the direction opposite the light incident face after converting the wavelength of the incident light. The surface of the substrate may be a reflecting face at least in part. The reflecting face may be formed at least in the region in which the wavelength conversion layer is disposed. The reflecting face may be formed with a material including at least one selected from the group consisting of silver and aluminum, for example.

The wavelength conversion layer disposed on the substrate includes s binder and at least the rare earth aluminate phosphor. The binder for the wavelength conversion layer may be an organic or inorganic binder. An organic binder may include a hardened resin material, preferably a hardened light transmissive resin material. Examples of resins include thermosetting resins, such as epoxy resins, silicone resins, epoxy modified silicone resins, and modified silicone resins. The resin containing a silicone resin tends to excel in heat resistance, light resistance, and the like. Examples of silicone resins or modified silicone resins may include at least one selected from the group consisting of phenyl silicone resin, modified phenyl silicone resin, dialkylsilicone resin, and modified dialkylsilicone resin. Examples of inorganic binders include glass, ceramics, aluminum oxide, and the like. The wavelength conversion layer may contain a phosphor having a different composition or peak emission wavelength from that of the rare earth aluminate phosphor described above.

The light emitting device can configure a projector which will be described later, for example. The light emitting device can be used not only as a light source device for projectors, but also as a light emitting device included in a light source for general lighting fixtures such as ceiling lights, special lighting equipment, such as spotlights, stadium lights, and studio lights, automotive lighting devices such as headlights, projectors such as head-up displays, endoscope lights, imaging devices, such as digital cameras, mobile phones, and smartphones, and liquid crystal display devices, such as personal computer (PC) monitors, notebook PCs, televisions, personal digital assistants (PDA), smartphones, tablet PCs, and mobile phones.

### Projector

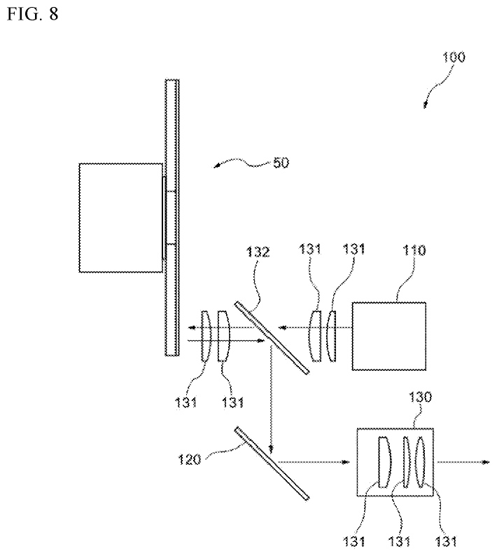

An example of projector that includes the light emitting device described above, an image display system, and a projection optical system will be explained with reference to FIG. 8. FIG. 8 is a schematic configuration diagram of a projector 100. The projector 100 includes a light source 110, a wavelength conversion member 50, an image display system 120, and a projection optical system 130. In the projector 100, mixed light of the light from the light source 110 and the light from the light source 110 which is converted by the wavelength conversion member 50 is irradiated on the image display system 120. The image display system 120 converts the light into an image before projecting externally via the projection optical system 130.

The details of the light source 110 and the wavelength conversion member 50 included in the projector 100 are as described above. The image display system 120 displays the image projected by the projector 100. For the image display system 120, a liquid crystal panel, digital mirror device (DMD) or the like can be used. The projection optical system 130 externally projects the light exiting the wavelength conversion member 50 that is converted into an image by the image display system 120. The projection optical system 130 includes multiple lenses 131, allowing for zooming and focusing adjustments. The projector 100 includes, in addition to the constituents described above, a lens 131, a dichroic mirror 132, and the like. Depending on the design of the projector 100, it may include a mirror, dichroic mirror, lens, prism, or the like that are not shown in FIG. 8.

### Method of Manufacturing Rare Earth Aluminate Phosphor

A method of manufacturing a rare earth aluminate phosphor includes:
providing a raw material mixture having a preparatory composition represented by the formula (I) below by mixing a compound containing at least one rare earth element R¹ selected from the group consisting of Y, La, Lu, Gd, and Tb, a compound containing Ce, a compound containing Al, and a compound containing at least one element M¹ selected as needed from Ga and Sc;
obtaining first rare earth aluminate phosphor particles having a composition represented by the formula (I) below by conducting a first heat treatment on the raw material mixture; and
obtaining a rare earth aluminate phosphor including, on the surfaces of the first rare earth aluminate phosphor particles, second rare earth aluminate phosphor parts having a composition with a Ga molar ratio higher than a Ga molar ratio in one mole of the composition represented by the formula (I) below by conducting a second heat treatment on the first rare earth aluminate phosphor particles and a compound containing Ga at a temperature lower than a temperature set in the first heat treatment, wherein
in conducting the second heat treatment, a mixing ratio of the compound containing Ga is 0.5 parts by mass or higher and lower than 5.0 parts by mass per 100 parts by mass of the first rare earth aluminate phosphor particles,
the second heat treatment is not conducted on the first rare earth aluminate phosphor particles together with the compound containing the rare earth element R¹, the compound containing Ce, the compound containing Al, and the compound containing Sc.

(R¹₁₋ₙCeₙ)₃(Al₁₋ₘM¹ₘ)₅ₖO₁₂ (I)

(In the formula (I), R¹ is at least one element selected from the group consisting of Y, La, Lu, Gd, and Tb, M¹ is at least one element selected from the group consisting of Ga and Sc, and m, n, and k respectively satisfy 0≤m≤0.012, 0.001≤n≤0.017, and 0.95≤k≤1.10.)

In conducting the second heat treatment, if the compound containing Ga and the first rare earth aluminate phosphor particles are subject to the second heat treatment together with a compound containing a rare earth element R¹, a compound containing Ce, a compound containing Al, and a compound containing Sc which are raw materials for the first rare earth aluminate phosphor particles, the compound containing a rare earth element R¹, the compound containing Ce, the compound containing Al, and the compound containing Sc allow the crystal structure of the first rare earth aluminate phosphor particles to grow, making the second rare earth aluminate phosphor parts having a larger Ga molar ratio than the Ga molar ratio of the first rare earth aluminate phosphor particles less apt to form. It is preferable to obtain a rare earth aluminate phosphor having, on the surfaces of the first rare earth aluminate phosphor particles, second rare earth aluminate phosphor parts by conducting the second heat treatment only on the first rare earth aluminate phosphor particles and a compound containing Ga.

In providing a raw material mixture, the compound containing at least one rare earth element R¹ selected from the group consisting of Y, La, Lu, Gd, and Tb, the compound containing Ce, the compound containing Al, and the compound containing at least one element M¹ selected as needed from Ga and Sc can be oxides and at least one type of metal salts selected from the group consisting of oxalates, carbonates, chlorides, nitrates, and sulfates. The oxides and metal salts may be in the form of hydrates. Specific examples of oxides include Y₂O₃, La₂O₃, Lu₂O₃, Gd₂O₃, Tb₄O₇, CeO₂, Al₂O₃, Ga₂O₃, and Sc₂O₃. Specific examples of metal salts include YCl₃, Y₂(C₂O₄)₃, Y₂(CO₃)₃, Y(NO₃)₃, Y₂(SO₄)₃, LaCl₃, La₂(C₂O₄)₃, La₂(CO₃)₃, La(NO₃)₃, La₂(SO₄)₃, LuCl₃, Lu₂(C₂O₄)₃, Lu(NO₃)₃, Lu₂(SO₄)₃, GdCl₃, TbCl₃, CeCl₃, Ce₂(SO₄)₃, AlCl₃, Al(NO₃)₃, Al₂(SO₄)₃, GaCl₃, Ga(NO₃)₃, ScCl₃, and Sc(NO₃).

When subjecting the raw material mixture to the first heat treatment, a flux may be present. The flux may include a compound containing at least one element selected from the group consisting of Ba, Sr, Ca, Mg, and Mn. The compound containing at least one element selected from the group consisting of Ba, Sr, Ca, Mg, and Mn used as the flux is preferably a halide. The compound used as the flux among halides is preferably a fluoride or chloride, more preferably a fluoride. The compound used as the flux is more preferably BaF₂. Using BaF₂ as the flux can stabilize the garnet crystal structure of the rare earth aluminate phosphor particles, more readily achieving a composition of the garnet crystal structure. The content of the compound used as the flux is preferably in a range of 0.5% by mass to 10% by mass when the total of the raw materials including the flux is 100% by mass. Setting the flux content in the raw material mixture in the range of 0.5% by mass to 10% by mass can better promote the reactions among the raw materials, allowing solid-phase reactions to progress more uniformly to obtain rare earth aluminate phosphor particles having the target composition. Including a flux in the raw material mixture promotes the reactions among the raw material compounds and more readily facilitates uniform progression of solid-state reactions. The reactions are believed to be promoted because the temperature used to obtain the first rare earth aluminate phosphor particles during the heat treatment of the raw material mixture is substantially the same as or higher than the liquid phase formation temperature for the halide used as the flux.

For the raw material mixture, after adjusting and weighing the raw material compounds for the target preparatory composition, the compounds may be ground and mixed by using a dry grinder, such as a ball mill, vibrating mill, hammer mill, roll mill, or jet mill, triturated by using a mortar and a pestle, or mixed by using a mixer, such as a ribbon mixer, Henschel mixer, or V-blender. Both dry grinder and mixer can be used for grinding and mixing. Mixing may be dry mixing, or wet mixing with the addition of a solvent. Dry mixing is preferable because of the shorter process time than wet mixing, which leads to increased productivity.

In obtaining first rare earth aluminate phosphor particles by the first heat treatment, the raw material mixture may be placed in a crucible or boat formed of carbon materials such as graphite, boron nitride (BN), aluminum oxide, tungsten, or molybdenum when subjected to the first heat treatment. For the first heat treatment, for example, an electric furnace, gas furnace, or the like can be used.

The first heat treatment temperature is preferably in a range of 1400° C. to 1800° C., more preferably in a range of 1450° C. to 1700° C. from the standpoint of crystal structure stability of the first rare earth aluminate phosphor particles.

The first heat treatment duration differs depending on the rate of temperature increase, heat treatment atmosphere, and the like, and is preferably one hour or more, more preferably 3 hours or more, even more preferably 5 hours or more, and preferably 20 hours at most, more preferably 18 hours at most, even more preferably 15 hours at most, after reaching the first heat treatment temperature.

The atmosphere in the first heat treatment is preferably a reducing atmosphere. The reducing atmosphere is preferably a nitrogen atmosphere containing a reducing hydrogen gas. Hydrogen gas in the reducing atmosphere is preferably 1% by volume or higher, more preferably 5% by volume or higher, even more preferably 10% by volume or higher. Nitrogen gas in the reducing atmosphere is preferably 70% by volume or higher, more preferably 80% by volume or higher, even more preferably 90% by volume or higher. In a highly reducing atmosphere, the compounds in the raw material mixture have good reactivity, and first rare earth aluminate phosphor particles can be obtained by conducting the first heat treatment under atmospheric pressure without being pressurized. Conducting the first heat treatment on the raw material mixture in a highly reducing atmosphere can reduce quadrivalent Ce(Ce⁴⁺) to trivalent Ce(Ce³⁺), thereby producing first rare earth aluminate phosphor particles including, inside of the first rare earth aluminate phosphor particles, an increased percentage of trivalent Ce which contributes to light emission.

The resultant first rare earth aluminate phosphor particles may be subjected to a dispersion process before the second heat treatment. An example of dispersion process includes wet dispersing the first rare earth aluminate phosphor particles in an aqueous medium such as water, wet sieving the particles, and conducting sedimentation sorting. The first rare earth aluminate phosphor particles may be wet dispersed in water, and coarse particles removed by wet sieving, and microparticles removed by sedimentation sorting, for example.

The resultant first rare earth aluminate phosphor particles may be subjected to an acid cleaning process. In the case of conducting a dispersion process, the first rare earth aluminate phosphor particles are preferably subjected to an acid cleaning process. The acid cleaning process removes the impurities adhering to the surfaces of the first rare earth aluminate phosphor particles. For aid cleaning, an aqueous hydrochloric acid solution is preferably used because it is readily available and inexpensive. The concentration of hydrochloric acid in the aqueous hydrochloric acid solution is preferably a concentration that does not affect the crystal structure of the first rare earth aluminate phosphor particles, preferably in a range of 1% by mass to 20% by mass, more preferably in a range of 5% by mass to 18% by mass.

In conducting a second heat treatment, only a compound containing Ga, together with the first rare earth aluminate phosphor particles, is subjected to the second heat treatment, which excludes conducting a second heat treatment on the first rare earth aluminate phosphor particles together with a compound containing a rare earth element R¹, a compound containing Ce, a compound containing Al, and a compound containing Sc. Subjecting only the first rare earth aluminate phosphor particles and a compound containing Ga to the second heat treatment can form second rare earth aluminate phosphor parts having a composition with a higher Ga molar ratio than the Ga molar ratio in one mole of the composition represented by the formula (I) on the surfaces of the first rare earth aluminate phosphor particles, thereby producing a rare earth aluminate phosphor having, on the surfaces of the first rare earth aluminate phosphor particles, the second rare earth aluminate phosphor parts having the composition with a higher Ga molar ratio than the Ga molar ratio in one mole of the composition represented by the formula (I).

In the second heat treatment, the mixing ratio of the compound containing Ga is preferably 0.5 parts by mass or higher and lower than 5.0 parts by mass, more preferably in a range of 0.5 parts by mass to 4.5 parts by mass, even more preferably in a range of 0.5 parts by mass to 4.0 parts by mass, even more preferably in a range of 1.0 parts by mass to 3.5 parts by mass, particularly preferably in a range of 1.0 parts by mass to 3.0 parts by mass per 100 parts by mass of the first rare earth aluminate phosphor particles. As long as the mixing ratio of the compound containing Ga is 0.5 parts by mass or higher and lower than 5.0 parts by mass per 100 parts by mass of the first rare earth aluminate phosphor particles in conducting the second heat treatment, the structural crystal defects of the first rare earth aluminate phosphor particles can be compensated for by Ga in the second rare earth aluminate phosphor parts, and protrusions and recessions are formed by the second rare earth aluminate phosphor parts on the surfaces of the first rare earth aluminate phosphor particles. This can produce a rare earth aluminate phosphor that emits light having high emission intensity and high emission efficiency when irradiated with light from a light source.

It is presumed for a rare earth aluminate phosphor that the content of Ga which demonstrates the effect of increasing the emission intensity measured by X-ray fluorescence spectrometry when the total of element R¹, Ce, Al, and element M¹ is 100% by mass is different depending on the element that constitutes the host crystal of a first rare earth aluminate phosphor particle. The reason is unclear as to why the content ratio of Ga which demonstrates the effect of increasing the emission intensity measured by X-ray fluorescence spectrometry when the sum of element R¹, Ce, Al, and element M¹ is 100% by mass differs depending on the element constituting the host crystal of the first rare earth aluminate phosphor particle. It is presumed that, when the mass of the element constituting the host crystals of the first rare earth aluminate phosphor particles is larger, the large mass first rare earth aluminate phosphor particles act as caps, making the volatilized gas less apt to escape when only the compound containing Ga, together with the first rare earth aluminate phosphor particles, is subjected to a second heat treatment. It is presumed that, when the mass of the element constituting the host crystals of the first rare earth aluminate phosphor particles is larger, the volatilized gas is less apt to escape because the first rare earth aluminate phosphor particles act as caps during the second heat treatment, and second rare earth aluminate phosphor parts are readily formed on the surfaces of the first rare earth aluminate phosphor particles. Thus, fine protrusions and recessions are created by the second rare earth aluminate phosphor parts on the surfaces of the first rare earth aluminate phosphor particles even if the Ga content measured by X-ray fluorescence spectrometry is 1.0% by mass or less when the total of element R¹, Ce, Al, and element M¹ is 100% by mass.

In conducting a second heat treatment, the second heat treatment temperature is lower than the first heat treatment temperature, and the difference between the first heat treatment temperature and the second heat treatment temperature is preferably 400° C. or larger, more preferably 450° C. or larger. Specifically, the second heat treatment temperature is preferably lower than the first heat treatment temperature by at least 400° C., more preferably lower by at least 450° C. The second heat treatment temperature is preferably in a range of 950° C. to 1200° C., and may be in a range of 950° C. to 1150° C. or in a range of 950° C. to 1100° C.

The compound containing Ga subjected to the second heat treatment together with the first rare earth aluminate phosphor particles is preferably an oxide, preferably gallium oxide (Ga₂O₃).

The second heat treatment duration differs depending on the rate of temperature increase, heat treatment atmosphere, and the like, and is preferably one hour or more, more preferably 3 hours or more, even more preferably 5 hours or more, and preferably 10 hours at most, more preferably 8 hours at most, even more preferably 6 hours at most, after reaching the second heat treatment temperature.

The atmosphere in the second heat treatment is preferably a reducing atmosphere. The reducing atmosphere is preferably the same as or similar to that used in the first heat treatment.

The rare earth aluminate phosphor having, on the surfaces of the first rare earth aluminate phosphor particles, the second rare earth aluminate phosphor part having a composition with a higher Ga molar ratio than the Ga molar ratio in one mole of the composition represented by the formula (I) resulting from the second heat treatment may be subjected to a dispersion process and/or acid cleaning process subsequent to the second heat treatment. The dispersion process for the rare earth aluminate phosphor can be the same as or similar to that for the first rare earth aluminate phosphor particles. The acid cleaning process for the rare earth aluminate phosphor can be the same as or similar to that for the first rare earth aluminate phosphor particles.

The rare earth aluminate phosphor having the second rare earth aluminate phosphor part having a composition with a higher Ga molar ratio than the Ga molar ratio in one mole of the composition represented by the formula (I) on the surfaces of the first rare earth aluminate phosphor particles resulting from the second heat treatment preferably has a Ga content of 0.5% by mass or higher and lower than 3.0% by mass measured by X-ray fluorescence spectrometry when the total of at least one element R¹ selected from the group consisting of Y, La, Lu, Gd, and Tb, Ce, Al, and at least one element M¹ selected from the group consisting of Ga and Sc is 100% by mass.

The rare earth aluminate phosphor that has the second rare earth aluminate phosphor part having a composition with a higher Ga molar ratio than the Ga molar ratio in one mole of the composition represented by the formula (I) on the surfaces of the first rare earth aluminate phosphor particles resulting from the second heat treatment preferably includes Y as a prerequisite for the element R¹, and a Ga content of 1.0% by mass or higher and lower than 3.0% by mass measured by X-ray fluorescence spectrometry when the total of at least one element R¹ selected from the group consisting of Y, La, Lu, Gd, and Tb, Ce, Al, and at least one element M¹ selected from the group consisting of Ga and Sc is 100% by mass.

The rare earth aluminate phosphor that has the second rare earth aluminate phosphor part having a composition with a higher Ga molar ratio than the Ga molar ratio in one mole of the composition represented by the formula (I) on the surfaces of the first rare earth aluminate phosphor particles resulting from the second heat treatment preferably includes Lu as a prerequisite for the element R¹, and a Ga content of 0.5% by mass or higher and lower than 3.0% by mass measured by X-ray fluorescence spectrometry when the total of at least one element R¹ selected from the group consisting of Y, La, Lu, Gd, and Tb, Ce, Al, and at least one element M¹ selected from the group consisting of Ga and Sc is 100% by mass.

The rare earth aluminate phosphor that has the second rare earth aluminate phosphor part having a composition with a higher Ga molar ratio than the Ga molar ratio in one mole of the composition represented by the formula (I on the surfaces of the first rare earth aluminate phosphor particles resulting from the second heat treatment preferably has the composition represented by the formula (II) when analyzed after dissolving the first rare earth aluminate phosphor particles and the second rare earth aluminate phosphor parts entirely. The rare earth aluminate phosphor having the composition represented by the formula (II) when analyzed after dissolving the first rare earth aluminate phosphor particles the second rare earth aluminate phosphor parts entirely can be confirmed to have the second rare earth aluminate phosphor part having a composition with a higher Ga molar ratio than the Ga molar ratio in one mole of the composition represented by the formula (I).

### EXAMPLES

The present invention will be more specifically explained below with reference to examples, but the present invention is not limited to these examples.

### Example 1

### Provision of Raw Material Mixture

Yttrium oxide (Y₂O₃), cerium oxide (CeO₂), aluminum oxide (Al₂O₃), and gallium oxide (Ga₂O₃), which were used as the raw materials, were weighed so as to satisfy Y:Ce:Al:Ga=2.988:0.012:4.94:0.06. The preparatory composition of the raw material mixture was a composition represented by the formula (I), the rare earth element R¹ was Y, the Ce molar ratio which is the product of variable n and 3 in which variable n was 0.004 (n=0.004), the element M¹ was Ga, the Ga molar ratio which is the product of variable m, 5, and variable k in which variable m was 0.012 (m=0.012) and variable k was 0.998 (k=0.998). The raw material mixture was provided by mixing the weighed raw materials by using a ball mill. The raw material mixture included a flux. As the flux, barium fluoride (BaF₂) was added, and the raw materials and the flux were mixed by using a ball mill. The content of the flux, BaF₂, was 2.5% by mass when the total of the raw materials and the flux was 100% by mass.

### First Heat Treatment

First rare earth aluminate phosphor particles were obtained by conducting a first heat treatment on the raw material mixture and flux placed in an alumina crucible in a reducing atmosphere at 1550° C. for 10 hours. After the first heat treatment, the first rare earth aluminate phosphor particles were placed in a container together with alumina balls and deionized water as dispersing medium, and a dispersion process was performed for 30 hours while rotating. Then coarse particles were removed by wet sieving. Then microparticles were removed by sedimentation sorting. The first rare earth aluminate phosphor particles resulting from sedimentation sorting were acid cleaned using an aqueous hydrochloric acid solution in which the hydrochloric acid concentration was 17% by mass, subsequently rinsed with water, separated and dried. The first rare earth aluminate phosphor particles had a composition represented by the formula (I), the rare earth element R¹ was Y, the Ce molar ratio which is the product of variable n and 3 in which variable n was 0.004 (n=0.004), the element M¹ was Ga, the Ga molar ratio which is the product of variable m, 5, and variable k in which variable m was 0.012 (m=0.012) and variable k was 0.998 (k=0.998).

### Second Heat Treatment

Gallium oxide (Ga₂O₃) as a compound containing Ga was added to the first rare earth aluminate phosphor particles such that the mixing ratio of the gallium oxide was 0.5 parts by mass per 100 mass parts of the first rare earth aluminate phosphor particles. By mixing the first rare earth aluminate phosphor particles and gallium oxide, placing the mixture in an alumina crucible, and conducting a second heat treatment in a reducing atmosphere at 1100° C. for 6 hours, a rare earth aluminate phosphor having, on the surfaces of the first rare earth aluminate phosphor particles having a composition represented by the formula (I), second rare earth aluminate phosphor part having a composition with a higher Ga molar ratio than the Ga molar ratio in one mole of the composition represented by the formula (I) was obtained. Subsequent to the second heat treatment, the resultant rare earth aluminate phosphor having second rare earth aluminate phosphor parts on the surfaces of the first rare earth aluminate phosphor particles was placed in the container with alumina balls and deionized water as dispersing medium, and subjected to a dispersion process while rotating for 30 hours. Then coarse particles were removed by wet sieving. Then microparticles were removed by sedimentation sorting. The rare earth aluminate phosphor resulting from sedimentation sorting was acid cleaned using an aqueous hydrochloric acid solution in which the hydrochloric acid concentration was 17% by mass, subsequently rinsed with water, separated and dried.

### Example 2

A rare earth aluminate phosphor having, on the surfaces of the first rare earth aluminate phosphor particles having a composition represented by the formula (I), the second rare earth aluminate phosphor parts having a composition with a higher Ga molar ratio than the Ga molar ratio in one mole of the composition represented by the formula (I) was obtained in a manner same as or similar to that in Example 1 except for adding gallium oxide (Ga₂O₃) to the first rare earth aluminate phosphor particles such that the gallium oxide mixing ratio was 1.0 part by mass per 100 parts by mass of the first rare earth aluminate phosphor particles in conducting the second heat treatment.

### Example 3

A rare earth aluminate phosphor having, on the surfaces of the first rare earth aluminate phosphor particles having a composition represented by the formula (I), the second rare earth aluminate phosphor parts having a composition with a higher Ga molar ratio than the Ga molar ratio in one mole of the composition represented by the formula (I) was obtained in a manner same as or similar to that in Example 1 except for adding gallium oxide (Ga₂O₃) to the first rare earth aluminate phosphor particles such that the gallium oxide mixing ratio was 2.0 parts by mass per 100 parts by mass of the first rare earth aluminate phosphor particles in conducting the second heat treatment.

### Example 4

A rare earth aluminate phosphor having on the surfaces of the first rare earth aluminate phosphor particles having a composition represented by the formula (I) the second rare earth aluminate phosphor parts having a composition with a higher Ga molar ratio than the Ga molar ratio in one mole of the composition represented by the formula (I) was obtained in a manner same as or similar to that in Example 1 except for adding gallium oxide (Ga₂O₃) to the first rare earth aluminate phosphor particles such that the gallium oxide mixing ratio was 3.0 parts by mass per 100 parts by mass of the first rare earth aluminate phosphor particles in conducting the second heat treatment.

### Comparative Example 1

The first rare earth aluminate phosphor particles in Example 1 not subjected to a second heat treatment and had substantially no second rare earth aluminate phosphor parts having a composition with a higher Ga molar ratio than the Ga molar ratio in one mole of the composition represented by the formula (I) on the surfaces of the first rare earth aluminate phosphor particles were used as the rare earth aluminate phosphor of Comparative Example 1.

### Comparative Example 2

A rare earth aluminate phosphor having on the surfaces of the first rare earth aluminate phosphor particles having a composition represented by the formula (I) the second rare earth aluminate phosphor parts having a composition with a higher Ga molar ratio than the Ga molar ratio in one mole of the composition represented by the formula (I), and a Ga content measured by X-ray fluorescence spectrometry was 3.0% by mass when the total of Y, Ce, Al, and Ga is 100% by mass was obtained in a manner same as or similar to that in Example 1 except for adding gallium oxide (Ga₂O₃) to the first rare earth aluminate phosphor particles such that the gallium oxide mixing ratio was 5.0 parts by mass per 100 parts by mass of the first rare earth aluminate phosphor particles in conducting the second heat treatment.

### Comparative Example 3

A rare earth aluminate phosphor having on the surfaces of the first rare earth aluminate phosphor particles having a composition represented by the formula (I) the second rare earth aluminate phosphor parts having a composition with a higher Ga molar ratio than the Ga molar ratio in one mole of the composition represented by the formula (I), and a Ga content of 4.26% by mass measured by X-ray fluorescence spectrometry when the total of Y, Ce, Al, and Ga is 100% by mass was obtained in a manner same as or similar to that in Example 1 except for adding gallium oxide (Ga₂O₃) to the first rare earth aluminate phosphor particles such that the gallium oxide mixing ratio was 7.5 parts by mass per 100 parts by mass of the first rare earth aluminate phosphor particles in conducting the second heat treatment.

### Comparative Example 4

A rare earth aluminate phosphor having on the surfaces of the first rare earth aluminate phosphor particles having a composition represented by the formula (I) the second rare earth aluminate phosphor parts having a composition with a higher Ga molar ratio than the Ga molar ratio in one mole of the composition represented by the formula (I), and a Ga content of 5.25% by mass measured by X-ray fluorescence spectrometry when the total of Y, Ce, Al, and Ga is 100% by mass was obtained in a manner same as or similar to that in Example 1 except for adding gallium oxide (Ga₂O₃) to the first rare earth aluminate phosphor particles such that the gallium oxide mixing ratio was 10.0 parts by mass per 100 parts by mass of the first rare earth aluminate phosphor particles in conducting the second heat treatment.

The evaluation described below were conducted on the rare earth aluminate phosphors of Example 1 to Example 4 which had, on the surfaces of the first rare earth aluminate phosphor particles having the composition represented by the formula (I), second rare earth aluminate phosphor parts having a composition with a higher Ga molar ratio than the Ga molar ratio in one mole of the composition represented by the formula (I). The rare earth aluminate phosphor of Comparative Example 1, which was not subjected to a second heat treatment, and had substantially no second rare earth aluminate phosphor parts on the surfaces of the first rare earth aluminate phosphor particles having the composition represented by the formula (I) was also evaluated as described below. The rare earth aluminate phosphors of Comparative Example 2 to 4 were also evaluated as descried below. Table 1 shows the results.

### Compositional Analysis of Rare Earth Aluminate Phosphor

The rare earth aluminate phosphors were analyzed by X-ray fluorescence spectrometry (XRF) by irradiating each sample with fluorescence X-ray using an X-ray fluorescence analyzer (ZSX Primus II manufactured by Rigaku Corporation) to measure the peak intensity of the Kα line of Y which is element R¹, the peak intensity of the Kα line of Al, the peak intensity of the Kα line of Ce, and the peak intensity of the Kα line of Ga which is element M¹. For Y which is element R¹, Al, Ce, and Ga which is element M¹, calibration curbs establishing the correlations between the concentrations and the X-ray intensities were provided by linear approximation by using the standard samples of their oxides (Y₂O₃, Al₂O₃, CeO₂, and Ga₂O₃). Based on the calibration curve for each element provided by using the standard sample, the concentration of the element in terms of oxide was obtained from the peak intensity of the element measured by the X-ray fluorescence analyzer. Based on the concentrations of the elements in terms of oxides, the Ga content in terms of oxide (% by mass) when the total of the concentrations of Y, Ce, Al, and Ga in terms of oxides is 100% by mass was obtained. In the composition of each rare earth aluminate phosphor represented by the formula (II) which included the first rare earth aluminate phosphor particles and the second rare earth aluminate phosphor parts, variable q is 0 (q=0) in the product of variable q representing the Sc molar ratio, 5, and variable k.

### Average Particle Size (Dbar) by FSSS Method

With respect to each of the rare earth aluminate phosphors in Examples and Comparative Examples, the average particle size was obtained by the FSSS method using a Fisher Sub-sieve Sizer Model 95 (manufactured by Fisher Scientific). Specifically, each sample of the rare earth aluminate phosphors was measured to a volume of 1 cm³, packed in a dedicated tubular container, and subjected to a dry air flow at constant pressure. From the relational expression of the transmitted air pressure and the porosity of the packed sample, the average particle size (Dbar) was obtained by the FSSS method.

### Chromaticity Coordinates, Peak Emission Wavelength, and Relative Emission Intensity

Excitation light having the peak wavelength of 450 nm was irradiated on each of the rare earth aluminate phosphors of Examples and Comparative Examples by using a quantum efficiency measurement system (QE-2000 manufactured by Ootsuka Electronics Co., Ltd.) to measure the emission spectrum in room temperature (about 25° C., 20° C. to 30° C.). From the emission spectrum, the chromaticity coordinates (x, y) in the chromaticity diagram of CIE1931 standard colorimetric system, the relative emission intensity (%), and the peak emission wavelength (λp(nm)) were measured. The relative emission intensity is a relative emission intensity (%) of a sample calculated by assuming the emission intensity of the rare earth aluminate phosphor of Comparative Example 1 as 100%.

### SEM Micrograph—Secondary Electron Image

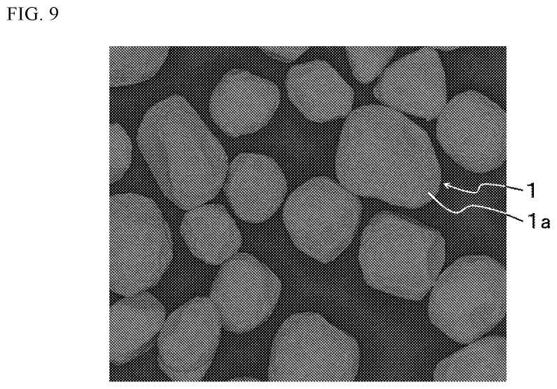

Using a scanning electron microscope (SEM, JIS-IT200, manufactured by JEOL, Ltd.), SEM micrographs, which are secondary electron images of phosphor particles were obtained. FIG. 9 is a SEM micrograph (secondary electron image) of the rare earth aluminate phosphor of Example 4.

### Ga Elemental Mapping Using Energy Dispersive X-Ray Fluorescence Spectrometer

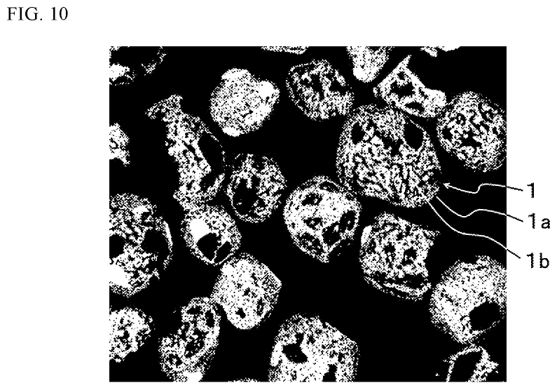

The image of each of the rare earth aluminate phosphors in Examples and Comparative Examples was captured by using a field emission scanning electron microscope (FE-SEM, product name: SU8230 manufactured by Hitachi High-Tech Corporation), the composition of the rare earth aluminate phosphor captured was analyzed and a Ga elemental map image was created by using an energy dispersive X-ray fluorescence spectrometer (EDX, SDD detector manufactured by HORIBA, Ltd., accelerating voltage: 5 kV). FIG. 10 is a binarized Ga elemental map image of the SEM micrograph of the rare earth aluminate phosphor of Example 4.

### Pixel Percentage (%)

The pixel percentage of each of the rare earth aluminate phosphors in Examples and Comparative Examples was obtained by calculating a first pixel total count p×1, which is the total number of pixels of one or more first rare earth aluminate phosphor particles in the SEM image described above, calculating a second total pixel count p×2, which is the total number of pixels of Ga in the second rare earth aluminate phosphor parts on the surfaces of the first rare earth aluminate phosphor particles in the Ga elemental map image of the image captured by the energy dispersive X-ray fluorescence spectrometer (EDX) described above, and dividing the second total pixel count p×2 by the first total pixel count p×1 (p×2/p×1×100). For the pixel percentage of the rare earth aluminate phosphor particles of each of Examples and Comparative Examples, specifically, the first pixel total count p×1 was obtained individually for each of the rare earth aluminate phosphor particles captured in a SEM micrograph, the second pixel total count p×2 was obtained individually for each rare earth phosphor particle in the Ga elemental map image of the second rare earth aluminate phosphor parts present on the surface of the first rare earth aluminate phosphor particle, individual pixel percentages (p×2/p×1×100) were calculated, and the arithmetic average value thereof was obtained. For the rare earth aluminate phosphor of Comparative Example 1, elemental mapping of Ga on the surfaces of the first rare earth aluminate phosphor particles could not be performed, and the second pixel total count p×2 could not be obtained.

### Light Emitting Device

Disk-shaped substrates of 33 mm in diameter and 0.47 mm in thickness formed of a metal containing aluminum were provided. The specular reflectance of the reflecting face of a substrate for 450 nm light was 89%.

Five parts by mass of dodecane was added to 100 parts by mass of a silicone resin and mixed by using a vacuum defoaming mixing machine, to which 300 parts by mass of a rare earth aluminate phosphor of an Example or Comparative Example was added and mixed in the vacuum defoaming mixing machine to obtain a phosphor composition. The resultant phosphor composition was applied to a substrate by screen printing to form a phosphor composition layer, and heat treated in a 60° C. oven for 4 hours, and then in a 150° C. oven for 4 hours to form a wavelength conversion layer having the thickness shown in Table 1 measured by the method described later. In this manner, wavelength conversion members of Examples and Comparative Examples were obtained.

Light emitting devices shown in FIG. 4 including the respective wavelength conversion members of Examples and Comparative Examples were manufactured.

### Average Thickness of Wavelength Conversion Layer

The average thickness of the wavelength conversion layer of each of the wavelength conversion members of Examples and Comparative Examples was calculated by subtracting the arithmetic average value of the thicknesses of the substrate measured at six locations from the arithmetic average value of the total thicknesses of the wavelength conversion layer and the substrate measured at the six locations. The total thickness of the wavelength conversion layer and the substrate, and the thickness of the substrate alone in each case were measured by using a contact thickness gauge. Relative Output Intensity (%)

In each of the light emitting devices of Examples and Comparative Examples, laser light having a 450 nm wavelength and 90 W intensity from a laser diode was irradiated on the wavelength conversion member via a dichroic mirror such that the beam diameter of the incident light was 1 mm (φ 1 mm). Then the radiant flux of the light emitted from the same face as the laser light incident face was separated by the dichroic mirror and the intensity of the emitted light was measured by using an integrating sphere. Using the value obtained by dividing the emitted light intensity by the incident light intensity as the output intensity (emitted light intensity/incident light intensity) of each light emitting device, the relative output intensity (%) was obtained by using the output intensity of the light emitting device having the rare earth aluminate phosphor of Comparative Example 1 as 100%.

### Surface Temperature (° C.)

In each of the light emitting devices of Examples and Comparative Examples, the surface temperature of the wavelength conversion layer when hit by the light having 88.5 W intensity from the laser diode was measured by using an infrared thermography-based thermometer.

TABLE 1

| | | Rare Earth Aluminate Phosphor | | | | | | | | | |
|---|---|---|---|---|---|---|---|---|---|---|---|
| | | Analyzed | | | | | | | | | |
| | Gallium | Value | Aalyzed Composition | | | | | | | | |
| | Oxide | Ga | | | | | | | | Al and | |
| | Ga₂O₃ | Content | Y | Ce | | Al | | Ga | | Ga Total | |
| | Part by | % by | Molar | Molar | Vari- | Molar | 1-vari- | Molar | Vari- | Molar | Vari- |
| | Mass | Mass | Ratio | Ratio | able n | Ratio | able p | Ratio | able p | Ratio | able k |
| Example 1 | 0.5 | 1.03 | 2.988 | 0.012 | 0.004 | 4.89 | 0.984 | 0.08 | 0.016 | 4.97 | 0.994 |
| Example 2 | 1.0 | 1.44 | 2.987 | 0.013 | 0.004 | 4.92 | 0.984 | 0.08 | 0.016 | 5.00 | 1.000 |
| Example 3 | 2.0 | 1.93 | 2.987 | 0.013 | 0.004 | 4.92 | 0.987 | 0.11 | 0.022 | 5.03 | 1.006 |
| Example 4 | 3.0 | 2.49 | 2.987 | 0.013 | 0.004 | 4.89 | 0.970 | 0.15 | 0.030 | 5.04 | 1.008 |
| Comparative | — | 0.96 | 2.987 | 0.013 | 0.004 | 4.93 | 0.988 | 0.06 | 0.012 | 4.99 | 0.998 |
| Ex. 1 | | | | | | | | | | | |
| Comparative | 5.0 | 3.00 | 2.987 | 0.013 | 0.004 | 4.87 | 0.966 | 0.17 | 0.034 | 5.04 | 1.008 |
| Ex. 2 | | | | | | | | | | | |
| Comparative | 7.5 | 4.26 | 2.988 | 0.012 | 0.004 | 4.90 | 0.950 | 0.26 | 0.050 | 5.16 | 1.032 |
| Ex. 3 | | | | | | | | | | | |
| Comparative | 10.0 | 5.25 | 2.988 | 0.012 | 0.004 | 4.80 | 0.938 | 0.32 | 0.063 | 5.12 | 1.024 |
| Ex. 4 | | | | | | | | | | | |

| | | | | | | | Light | | |
|---|---|---|---|---|---|---|---|---|---|
| | | | | | | | Emitting Device | | |
| | | | | | | | Wave- | | |
| | | | | | | | length | | |
| | Rare Earth Aluminate Phosphor | | | | | | Conversion | | |
| | | Median | | | | Peak | Layer | | |
| | | Particle | | | Relative | Wave- | Avg | Relative | |
| | Pixel % | Size | Chromaticity | | Emission | length | Thick- | Output | Surface |
| | px2/px1 | Dbar | Coordinates | | Intensity | λp | ness | Intensity | Temp. |
| | % | μm | x | y | % | nm | μm | % | ° C. |
| Example 1 | 11.83 | 30.0 | 0.419 | 0.557 | 100.1 | 540 | 148 | 99.0 | 131.7 |
| Example 2 | 26.43 | 31.5 | 0.418 | 0.556 | 101.1 | 540 | 159 | 101.4 | 127.2 |
| Example 3 | 59.18 | 30.5 | 0.417 | 0.557 | 101.7 | 539 | 163 | 100.9 | 125.2 |
| Example 4 | 76.72 | 30.5 | 0.416 | 0.557 | 100.8 | 542 | 159 | 100.8 | 126.4 |
| Comparative | — | 31.5 | 0.419 | 0.556 | 100.0 | 540 | 156 | 100.0 | 128.2 |
| Ex. 1 | | | | | | | | | |
| Comparative | 62.52 | 30.0 | 0.413 | 0.559 | 98.9 | 540 | 149 | 98.7 | 130.9 |
| Ex. 2 | | | | | | | | | |
| Comparative | 65.79 | 27.5 | 0.411 | 0.560 | 98.8 | 537 | 152 | 95.6 | 133.0 |
| Ex. 3 | | | | | | | | | |
| Comparative | 70.32 | 28.5 | 0.410 | 0.560 | 96.8 | 539 | 155 | 97.7 | 130.5 |
| Ex. 4 | | | | | | | | | |

The rare earth aluminate phosphors of Examples 1 to 4 had, on the surfaces of the first rare earth aluminate phosphor particles having the composition represented by the formula (I), second rare earth aluminate phosphor parts having a composition with a higher Ga molar ratio than the Ga molar ratio in one mole of the composition represented by the formula (I). The rare earth aluminate phosphors of Examples 1 to 4 had the composition represented by the formula (II) analyzed after dissolving the first rare earth aluminate phosphor particles and the second rare earth aluminate phosphor parts entirely. The compositions of the rare earth aluminate phosphors of Examples 1 to 4 analyzed after dissolving the first rare earth aluminate phosphor particles and the second rare earth aluminate phosphor parts entirely had a higher Ga molar ratio than the Ga molar ratio in the first rare earth aluminate phosphor particles having a composition represented by the formula (I), and the presence of the second rare earth aluminate phosphor parts having a composition with a larger Ga molar ratio than the Ga molar ratio in one mole of the composition represented by the formula (I) on the surfaces of the first rare earth aluminate phosphor particles was confirmed.

The rare earth aluminate phosphors of Examples 1 to 4 had a Ga content of 1.0% by mass or higher and lower than 3.0% by mass measured by the X-ray fluorescence analyzer when the total of Y which is element R¹, Al, Ce, and Ga which is element M¹ was 100% by mass, and had higher relative emission intensities when irradiated with the light from the light source than the rare earth aluminate phosphor of Comparative Example 1, which had substantially no second rare earth aluminate phosphor parts on the surfaces of the first rare earth aluminate phosphor particles, because the structural crystal defects of the first rare earth aluminate phosphor particles were compensated for by the second rare earth aluminate phosphor parts having a composition with a higher Ga molar ratio than the Ga molar ratio in one mole of the composition represented by the formula (I), and protrusions and recessions formed by the second rare earth aluminate phosphor parts were present on the surfaces of the first rare earth aluminate phosphor particles.

The light emitting device including the wavelength conversion member containing the rare earth aluminate phosphor of Example 1 maintained the relative output intensity that was substantially the same as that of the light emitting device including the wavelength conversion member containing the rare earth aluminate phosphor of Comparative Example 1.

The light emitting devices including the wavelength conversion members respectively containing the rare earth aluminate phosphors of Examples 2 to 4 had higher relative output intensities than the light emitting device including the wavelength conversion member containing the rare earth aluminate phosphor of Comparative Example 1 which did not have second rare earth aluminate phosphor parts on the surfaces of the first rare earth aluminate phosphor particles. The wavelength conversion members of Examples 2 to 4 respectively using the rare earth aluminate phosphors of Examples 2 to 4 had lower surface temperatures than that of the wavelength conversion member containing the rare earth aluminate phosphor of Comparative Example 1 which substantially did not have second rare earth aluminate phosphor parts on the surfaces of the first rare earth aluminate phosphor particles, because the rare earth aluminate phosphors that had second rare earth aluminate phosphor parts on the surfaces of the first rare earth aluminate phosphor particles allowed the protrusions and the recessions formed by the second rare earth aluminate phosphor parts to scatter the light from the light emitting element, the light source, efficiently absorbing the light and efficiently converting the wavelength thereof.

The pixel percentages of the rare earth aluminate phosphors of Examples 1 to 4 that had, on the surfaces of the first rare earth aluminate phosphor particles having the composition represented by the formula (I), the second rare earth aluminate phosphor parts having a composition with a higher Ga molar ratio than the Ga molar ratio in one mole of the composition represented by the formula (I) were in the 5.0% to 80.0% range.

The rare earth aluminate phosphors of Examples 1 to 4 had higher relative emission intensities than the rare earth aluminate phosphor of Comparative Example 1 which had substantially no second rare earth aluminate phosphor parts on the surfaces of the first rare earth aluminate phosphor particles when irradiated with light from the light source because variable p in the product of variable p, 5, and variable k representing the Ga molar ratio in the compositions represented by the formula (II) analyzed after dissolving the first rare earth aluminate phosphor particles and the second rare earth aluminate phosphor parts entirely was higher than 0.012 and lower than 0.034 (0.012<p<0.034), the structural crystal defects of the first rare earth aluminate phosphor particles were compensated for by the second rare earth aluminate phosphor parts having a composition with a higher Ga molar ratio than the Ga molar ratio in one mole of the composition represented by the formula (I), and protrusions and recessions formed by the second rare earth aluminate phosphor parts were present on the surfaces of the first rare earth aluminate phosphor particles.

FIG. 9 is a SEM micrograph (secondar electron image) of the rare earth aluminate phosphor of Example 4. As shown in FIG. 9, the rare earth aluminate phosphor of Example 4 had multiple second rare earth aluminate phosphor parts on the surfaces of the first rare earth aluminate phosphor particles which resulted in the presence of fine protrusions and recessions. The rare earth aluminate phosphor of Example 4 had higher relative emission intensity than the rare earth aluminate phosphor of Comparative Example 1 which had substantially no second rare earth aluminate phosphor parts on the surfaces of the first rare earth aluminate phosphor particles because it allowed the fine protrusions and recessions formed by the second rare earth aluminate phosphor parts on the surfaces of the first rare earth aluminate phosphor particles to readily scatter the irradiated light from the light source, which improved the absorption of the light from the light source and improved the wavelength conversion efficiency of the rare earth aluminate phosphor particles. The light emitting device including the wavelength conversion member containing the rare earth aluminate phosphor of Example 4 had higher relative output intensity than the light emitting device using the rare earth aluminate phosphor of Comparative Example 1 which had substantially no second rare earth aluminate phosphor parts on the surfaces of the first rare earth aluminate phosphor particles.

FIG. 10 is a binarized Ga elemental map image of the SEM micrograph of the rare earth aluminate phosphor 1 of Example 4. As shown in FIG. 10, in the rare earth aluminate phosphor 1 of Example 4, multiple second rare earth aluminate phosphor parts 1b were sporadically located on the surface of a first rare earth aluminate phosphor particle 1a. The rare earth aluminate phosphor 1 of Example 4 was such that the structural crystal defects of the surface of the first rare earth aluminate phosphor particle 1a were compensated for by the Ga contained in the sporadically located second rare earth aluminate phosphor parts 1b. Furthermore, the rare earth aluminate phosphor 1 of Example 4 was able to allow the fine protrusions and recessions formed by the second rare earth aluminate phosphor parts 1b sporadically located on the surface of the first rare earth aluminate phosphor particle 1a to more readily scatter the light irradiated by the light source, which improved the absorption of the light from the light source and improved the wavelength conversion efficiency of the first rare earth aluminate phosphor particle 1a. The rare earth aluminate phosphor of Example 4 had higher relative emission intensity than the rare earth aluminate phosphor of Comparative Example 1 which had substantially no second rare earth aluminate phosphor parts on the surfaces of the first rare earth aluminate phosphor particles. The light emitting device including the wavelength conversion member containing the rare earth aluminate phosphor of Example 4 had higher relative output intensity than the light emitting device using the rare earth aluminate phosphor of Comparative Example 1 which had substantially no second rare earth aluminate phosphor parts on the surfaces of the first rare earth aluminate phosphor particles.

The rare earth aluminate phosphors of Comparative Examples 2 to 4 had a Ga content of 3.0% by mass or higher measured by X-ray fluorescence spectrometry when the total of Y which is element R¹, Ce, Al, and Ga which is element M¹ was 100% by mass, which increased the second rare earth aluminate phosphor parts present on the surfaces of the first rare earth aluminate phosphor particles, reduced the excitation light wavelength conversion efficiency, and resulted in lower relative emission intensities than the rare earth aluminate phosphor of Comparative Example 1. The light emitting devices including the wavelength conversion members containing the rare earth aluminate phosphors of Comparative Examples 2 to 4 had lower relative output intensities than the light emitting device using the rare earth aluminate phosphor of Comparative Example 1 which had substantially no second rare earth aluminate phosphor parts on the surfaces of the first rare earth aluminate phosphor particles. The rare earth aluminate phosphors of Comparative Examples 2 to 4 had excessive second rare earth aluminate phosphor parts on the surfaces of the first rare earth aluminate phosphor particles, and were not able to efficiently absorb the light from the light source or covert the wavelength thereof. The wavelength conversion members using the rare earth aluminate phosphors of Comparative Examples 2 to 4 had higher surface temperatures than the wavelength conversion member of Comparative Example 1 which used the rare earth aluminate phosphor of Comparative Example 1.

### Example 5

### Provision of Raw Material Mixture

Lutetium oxide (Lu₂O₃), cerium oxide (CeO₂), aluminum oxide (Al₂O₃), and gallium oxide (Ga₂O₃), which were used as the raw materials, were weighed so as to satisfy Lu:Ce:Al:Ga=2.982:0.018:5.08:0.010. The preparatory composition of the raw material mixture was a composition represented by the formula (I), the rare earth element R¹ was Lu, the Ce molar ratio which is the product of variable n and 3 in which variable n was 0.006 (n=0.006), the element M¹ was Ga, the Ga molar ratio which is the product of variable m, 5, and variable k in which variable m is 0.010 (m=0.010) and variable k is 1.026 (k=1.062). The raw material mixture was obtained by mixing the weighed raw materials by using a ball mill. The raw material mixture included a flux. As the flux, barium fluoride (BaF₂) was added, and the raw materials and the flux were mixed by using a ball mill. The content of the flux, BaF₂, was 2.5% by mass when the total of the raw materials and the flux was 100% by mass.

### First Heat Treatment

First rare earth aluminate phosphor particles were obtained by conducting a first heat treatment on the raw material mixture and flux placed in an alumina crucible in a reducing atmosphere at 1625° C. for 10 hours. After the first heat treatment, the first rare earth aluminate phosphor particles were placed in a container together with alumina balls and deionized water, dispersing medium, and a dispersion process was performed for 30 hours while rotating. Then coarse particles were removed by wet sieving. Then microparticles were removed by sedimentation sorting. The first rare earth aluminate phosphor particles resulting from sedimentation sorting were acid cleaned using an aqueous hydrochloric acid solution in which the hydrochloric acid concentration was 17% by mass, subsequently rinsed with water, separated and dried. The first rare earth aluminate phosphor particles had a composition represented by the formula (I), the rare earth element R¹ was Lu, the Ce molar ratio which is the product of variable n and 3 in which variable n was 0.006 (n=0.006), the element M¹ was Ga, the Ga molar ratio which is the product of variable m, 5, and variable k in which variable m was 0.010 (m=0.010) and variable k was 1.026 (k=1.026).

### Second Heat Treatment

Gallium oxide (Ga₂O₃) as a compound containing Ga was added to the first rare earth aluminate phosphor particles such that the mixing ratio of the gallium oxide was 0.5 parts by mass per 100 mass parts of the first rare earth aluminate phosphor particles. By mixing the first rare earth aluminate phosphor particles and gallium oxide, placing the mixture in an alumina crucible, and conducting a second heat treatment in a reducing atmosphere at 1100° C. for 6 hours, a rare earth aluminate phosphor having, on the surfaces of the first rare earth aluminate phosphor particles having the composition represented by the formula (I), second rare earth aluminate phosphor part having a composition with a higher Ga molar ratio than the Ga molar ratio in one mole of the composition represented by the formula (I was obtained. Subsequent to the second heat treatment, the resultant rare earth aluminate phosphor having second rare earth aluminate phosphor parts on the surfaces of the first rare earth aluminate phosphor particles was placed in the container with alumina balls and deionized water, dispersing medium, and subjected to a dispersion process while rotating for 30 hours. Then coarse particles were removed by wet sieving. Then microparticles were removed by sedimentation sorting. The rare earth aluminate phosphor resulting from sedimentation sorting was acid cleaned using an aqueous hydrochloric acid solution in which the hydrochloric acid concentration was 17% by mass, subsequently rinsed with water, separated and dried.

### Example 6

A rare earth aluminate phosphor having on the surfaces of the first rare earth aluminate phosphor particles having the composition represented by the formula (I) the second rare earth aluminate phosphor parts having a composition with a higher Ga molar ratio than the Ga molar ratio in one mole of the composition represented by the formula (I) was obtained in a manner the same as or similar to that in Example 5 except for adding gallium oxide (Ga₂O₃) to the first rare earth aluminate phosphor particles such that the gallium oxide mixing ratio was 1.0 part by mass per 100 parts by mass of the first rare earth aluminate phosphor particles in conducting the second heat treatment. The rare earth aluminate phosphor particles of Examples 5 to 8 had a composition represented by the formula (I), the rare earth element R¹ was Lu, and variables n, m, and k were as shown in Table 2.

### Example 7

A rare earth aluminate phosphor having on the surfaces of the first rare earth aluminate phosphor particles having the composition represented by the formula (I) the second rare earth aluminate phosphor parts having a composition with a higher Ga molar ratio than the Ga molar ratio in one mole of the composition represented by the formula (I) was obtained in a manner same as or similar to that in Example 5 except for adding gallium oxide (Ga₂O₃) to the first rare earth aluminate phosphor particles such that the gallium oxide mixing ratio was 1.5 parts by mass per 100 parts by mass of the first rare earth aluminate phosphor particles in conducting the second heat treatment.

### Example 8

A rare earth aluminate phosphor having on the surfaces of the first rare earth aluminate phosphor particles having the composition represented by the formula (I) the second rare earth aluminate phosphor parts having a composition with a higher Ga molar ratio than the Ga molar ratio in one mole of the composition represented by the formula (I) was obtained in a manner same as or similar to that in Example 5 except for adding gallium oxide (Ga₂O₃) to the first rare earth aluminate phosphor particles such that the gallium oxide mixing ratio was 2.0 parts by mass per 100 parts by mass of the first rare earth aluminate phosphor particles in conducting the second heat treatment.

### Comparative Example 5

The first rare earth aluminate phosphor particles in Example 5 not subjected to the second heat treatment and had substantially no second rare earth aluminate phosphor parts having a composition with a higher Ga molar ratio than the Ga molar ratio in one mole of the composition represented by the formula (I) on the surfaces of the first rare earth aluminate phosphor particles were used as the rare earth aluminate phosphor of Comparative Example 5.

The rare earth aluminate phosphors of Example 5 to Example 8 had, on the surfaces of the first rare earth aluminate phosphor particles having the composition represented by the formula (I), second rare earth aluminate phosphor parts having a composition with a higher Ga molar ratio than the Ga molar ratio in one mole of the composition represented by the formula (I). The rare earth aluminate phosphors were analyzed and evaluated, in a manner same as or similar to that in Example 1, in terms of compositional analysis, average particle size (Dbar) by the FSSS method, chromaticity coordinates, peak emission wavelength and relative emission intensity, SEM micrograph-secondary electron image, Ga elemental mapping by using an energy dispersive X-ray fluorescence spectrometer, and pixel percentage (%) (p×2/p×1). The rare earth aluminate phosphor of Comparative Example 5, which was not subjected to a second heat treatment, and had substantially no second rare earth aluminate phosphor parts formed on the surfaces of the first rare earth aluminate phosphor particles having the composition represented by the formula (I) was also analyzed and evaluated in a manner same as or similar to that in Example 5. Table 2 shows the results. The compositional analysis was conducted in a manner same as or similar to that in Example 1, except for measuring the peak intensity of the Kα line of Lu which is element R¹ by irradiating the rare earth aluminate phosphor with fluorescence X-ray using the X-ray fluorescence analyzer (ZSX Primus II manufactured by Rigaku Corporation) in the analysis according to X-ray fluorescence spectrometry (XRF), providing a calibration curve establishing the correlation between the concentrations of the standard sample of the oxide containing Lu which is element R¹ (Lu₂O₃) and the X-ray intensities of the standard sample by linear approximation, obtaining, based on the calibration curves for the elements provided by using the standard samples, the concentrations of the elements in terms of oxides from the peak intensities of the elements measured by the X-ray fluorescence analyzer, and obtaining, based on the concentrations of the element in terms of oxides, the Ga content in terms of oxide (% by mass) using the total of the concentrations of Lu, Ce, Al, and Ga in terms of oxides of 100% by mass. In the compositions of the rare earth aluminate phosphors including the resultant first rare earth aluminate phosphor particles and the second rare earth aluminate phosphor parts represented by the formula (II), variable q is 0 (q=0) in the product of variable representing the Sc molar ratio q, 5, and variable k.

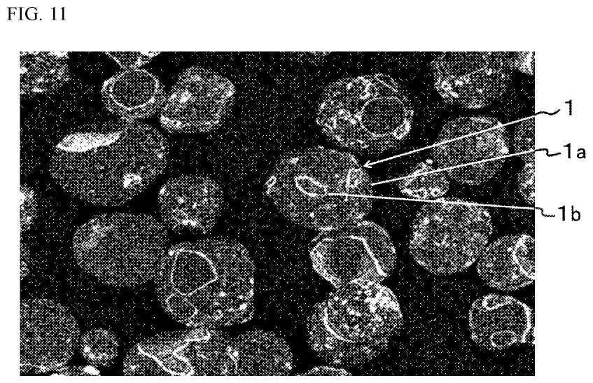

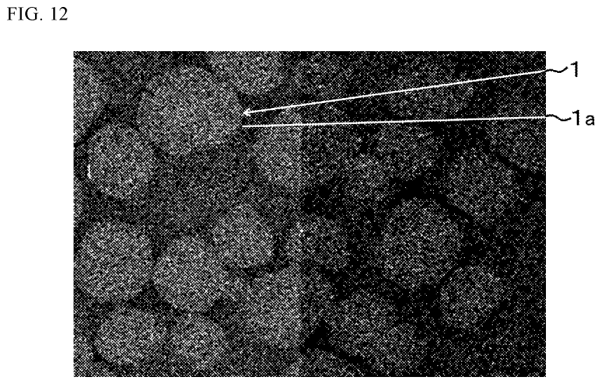

FIG. 11 is a binarized Ga elemental map image of a SEM micrograph of the rare earth aluminate phosphor of Example 5. FIG. 12 is a binarized Ga elemental map image of a SEM micrograph of the rare earth aluminate phosphor of Comparative Example 5.

Using the rare earth aluminate phosphors of Examples 5 to 8, light emitting devices were manufactured in a manner same as or similar to that in Example 1. Using the rare earth aluminate phosphor of Comparative Example 5, a light emitting device was manufactured in a manner same as or similar to that in Example 1. For each of the light emitting device manufactured, the average thickness of the wavelength conversion layer, the relative output intensity (%), and the surface temperature (° C.) were measured in a manner same as or similar to that in Example 1. Table 2 shows the results.

TABLE 2

| | | Rare Earth Aluminate Phosphor | | | | | | | | | |
|---|---|---|---|---|---|---|---|---|---|---|---|
| | | Analyzed | | | | | | | | | |
| | Gallium | Value | Aalyzed Composition | | | | | | | | |
| | Oxide | Ga | | | | | | | | Al and | |
| | Ga₂O₃ | Content | Lu | Ce | | Al | | Ga | | Ga Total | |
| | Part by | % by | Molar | Molar | Vari- | Molar | 1-vari- | Molar | Vari- | Molar | Vari- |
| | Mass | Mass | Ratio | Ratio | able n | Ratio | able p | Ratio | able p | Ratio | able k |
| Exam- | 0.5 | 0.50 | 2.982 | 0.018 | 0.006 | 5.08 | 0.990 | 0.05 | 0.010 | 5.13 | 1.026 |
| ple 5 | | | | | | | | | | | |
| Exam- | 1.0 | 0.60 | 2.981 | 0.019 | 0.006 | 5.05 | 0.986 | 0.07 | 0.014 | 5.12 | 1.024 |
| ple 6 | | | | | | | | | | | |
| Exam- | 1.5 | 0.90 | 2.981 | 0.019 | 0.006 | 5.07 | 0.984 | 0.08 | 0.016 | 5.15 | 1.030 |
| ple 7 | | | | | | | | | | | |
| Exam- | 2.0 | 1.10 | 2.981 | 0.019 | 0.006 | 5.08 | 0.981 | 0.10 | 0.019 | 5.18 | 1.036 |
| ple 8 | | | | | | | | | | | |
| Compar- | — | 0.40 | 2.982 | 0.018 | 0.006 | 5.07 | 0.992 | 0.04 | 0.008 | 5.11 | 1.022 |
| ative | | | | | | | | | | | |
| Ex. 5 | | | | | | | | | | | |

| | | | | | | | Light | | |
|---|---|---|---|---|---|---|---|---|---|
| | | | | | | | Emitting Device | | |
| | | | | | | | Wave- | | |
| | | | | | | | length | | |
| | Rare Earth Aluminate Phosphor | | | | | | Conversion | | |
| | | Median | | | | Peak | Layer | | |
| | | Particle | | | Relative | Wave- | Avg | Relative | |
| | Pixel % | Size | Chromaticity | | Emission | length | Thick- | Output | Surface |
| | px2/px1 | Dbar | Coordinates | | Intensity | λp | ness | Intensity | Temp. |
| | % | μm | x | y | % | nm | μm | % | ° C. |
| Exam- | 11.83 | 31.5 | 0.339 | 0.584 | 98.9 | 525 | 145 | 102.1 | 148.2 |
| ple 5 | | | | | | | | | |
| Exam- | 26.43 | 30.5 | 0.340 | 0.584 | 100.8 | 533 | 143 | 103.1 | 146.0 |
| ple 6 | | | | | | | | | |
| Exam- | 59.18 | 30.5 | 0.339 | 0.583 | 99.9 | 529 | 150 | 101.7 | 147.0 |
| ple 7 | | | | | | | | | |
| Exam- | 76.72 | 30.5 | 0.339 | 0.583 | 101.7 | 530 | 154 | 101.2 | 150.2 |
| ple 8 | | | | | | | | | |
| Compar- | — | 31.0 | 0.340 | 0.583 | 100.0 | 534 | 143 | 100.0 | 150.3 |
| ative | | | | | | | | | |
| Ex. 5 | | | | | | | | | |

The rare earth aluminate phosphors of Examples 5 to 8 had, on the surfaces of the first rare earth aluminate phosphor particles having the composition represented by the formula (I), second rare earth aluminate phosphor parts having a composition with a higher Ga molar ratio than the Ga molar ratio in one mole of the composition represented by the formula (I). The rare earth aluminate phosphors of Examples 5 to 8 had a composition represented by the formula (II) analyzed after dissolving the first rare earth aluminate phosphor particles and the second rare earth aluminate phosphor parts entirely. The compositions of the rare earth aluminate phosphors of Examples 5 to 8 analyzed after dissolving the first rare earth aluminate phosphor particles and the second rare earth aluminate phosphor parts entirely had a higher Ga molar ratio than the Ga molar ratio in the first rare earth aluminate phosphor particles having the composition represented by the formula (I), and the presence of the second rare earth aluminate phosphor parts having a composition with a larger Ga molar ratio than the Ga molar ratio in one mole of the composition represented by the formula (I) on the surfaces of the first rare earth aluminate phosphor particles was confirmed.

The rare earth aluminate phosphors of Examples 5 to 8 had a Ga content of 0.5% by mass or higher and lower than 3.0% by mass, more specifically 0.5% by mass to 2.0% by mass, measured by the X-ray fluorescence analyzer when the total of Lu which is element R¹, Al, Ce, and Ga which is element M¹ was 100% by mass. The rare earth aluminate phosphors of Examples 5 to 8 had relative emission intensities that were substantially the same as or higher than the rare earth aluminate phosphor of Comparative Example 5, which had substantially no second rare earth aluminate phosphor parts on the surfaces of the first rare earth aluminate phosphor particles, when irradiated with the light from the light source, because the structural crystal defects of the first rare earth aluminate phosphor particles were compensated for by the second rare earth aluminate phosphor parts having a composition with a higher Ga molar ratio than the Ga molar ratio in one mole of the composition represented by the formula (I), and protrusions and recessions formed by the second rare earth aluminate phosphor parts were present on the surfaces of the first rare earth aluminate phosphor particles.

The light emitting devices including the wavelength conversion member containing the rare earth aluminate phosphors of Examples 5 to 8 had higher relative output intensities than the light emitting device including the wavelength conversion member containing the rare earth aluminate phosphor of Comparative Example 5 which did not have second rare earth aluminate phosphor parts on the surfaces of the first rare earth aluminate phosphor particles. The wavelength conversion members of Examples 5 to 8 respectively using the rare earth aluminate phosphors of Examples 5 to 8 had lower surface temperatures than that of the wavelength conversion member containing the rare earth aluminate phosphor of Comparative Example 5 which did not have second rare earth aluminate phosphor parts on the surfaces of the first rare earth aluminate phosphor particles, because the rare earth aluminate phosphors that had second rare earth aluminate phosphor parts on the surfaces of the first rare earth aluminate phosphor particles allowed the protrusions and the recessions formed by the second rare earth aluminate phosphor parts to scatter the light from the light emitting element, the light source, efficiently absorbing the light and efficiently converting the wavelength thereof.

The pixel percentages of the rare earth aluminate phosphors of Examples 5 to 8 which had, on the surfaces of the first rare earth aluminate phosphor particles having the composition represented by the formula (I), the second rare earth aluminate phosphor parts having a composition with a higher Ga molar ratio than the Ga molar ratio in one mole of the composition represented by the formula (I) were in the range of 5.0% to 80.0%, more specifically in the range of 10.0% to 80.0%.

With respect to the rare earth aluminate phosphors of Examples 5 to 8, variable p in the product of variable p, 5, and variable k representing the Ga molar ratio in the composition represented by the formula (II) analyzed after dissolving the first rare earth aluminate phosphor particles and the second rare earth aluminate phosphor parts entirely was 0.010 or higher and lower than 0.034 (0.010≤p<0.034), and the structural crystal defects of the first rare earth aluminate phosphor particles were compensated for by the second rare earth aluminate phosphor parts having a composition with a higher Ga molar ratio than the Ga molar ratio in one mole of the composition represented by the formula (I). The rare earth aluminate phosphors of Examples 5 to 8 had higher relative emission intensities than the rare earth aluminate phosphor of Comparative Example 5 which had substantially no second rare earth aluminate phosphor parts on the surfaces of the first rare earth aluminate phosphor particles when irradiated with the light from the light source because protrusions and recessions formed by the second rare earth aluminate phosphor parts were present on the surfaces of the first rare earth aluminate phosphor particles.

FIG. 11 is a binarized Ga elemental map image of a SEM micrograph of the rare earth aluminate phosphor 1 of Example 5. As shown in FIG. 11, in the rare earth aluminate phosphor 1 of Example 5, multiple second rare earth aluminate phosphor parts 1b were sporadically located on the surface of a first rare earth aluminate phosphor particle 1a. The rare earth aluminate phosphor 1 of Example 5 was such that the structural crystal defects of the surface of the first rare earth aluminate phosphor particle 1a were compensated for by the Ga contained in the sporadically located second rare earth aluminate phosphor parts 1b. Furthermore, the rare earth aluminate phosphor 1 of Example 5 was able to allow the fine protrusions and recessions formed by the second rare earth aluminate phosphor parts 1b sporadically located on the surface of the first rare earth aluminate phosphor particle 1a to more readily scatter the light from the light source, which improved the absorption of the light from the light source and improved the wavelength conversion efficiency of the first rare earth aluminate phosphor particle 1a. The rare earth aluminate phosphor of Example 5 had higher relative emission intensity than the rare earth aluminate phosphor of Comparative Example 5 which had substantially no second rare earth aluminate phosphor parts on the surfaces of the first rare earth aluminate phosphor particles. The light emitting device including the wavelength conversion member containing the rare earth aluminate phosphor of Example 5 had higher relative output intensity than the light emitting device using the rare earth aluminate phosphor of Comparative Example 5 which had substantially no second rare earth aluminate phosphor parts on the surfaces of the first rare earth aluminate phosphor particles.

The Ga content of the rare earth aluminate phosphor of Comparative Example 5 measured by X-ray fluorescence spectrometry was lower than 0.5% by mass, specifically lower than 0.4% by mass when the total of Lu which is element R¹, Ce, Al, and Ga which is element M¹ was 100% by mass, which resulted in scarcely present second rare earth aluminate phosphor parts on the surfaces of the first rare earth aluminate phosphor particles.

Even though the emission intensity of the rare earth aluminate phosphor of Comparative Example 5 did not decline, the light emitting device which had the wavelength conversion member containing the rare earth aluminate phosphor of Comparative Example 5 could not efficiently disperse the light from the light emitting element, the light source, because it had substantially no second rare earth aluminate phosphor particles on the surface of the first rare earth aluminate phosphor particles. It thus had lower relative output intensity than the light emitting devices including the wavelength conversion members using the rare earth aluminate phosphors of Example 5 to 8, and a high surface temperature.

FIG. 12 is a binarized Ga elemental map image of a SEM micrograph of the rare earth aluminate phosphor 1 of Comparative Example 5. As shown in FIG. 12, in the rare earth aluminate phosphor 1 of Comparative Example 5, almost no second rare earth aluminate phosphor parts were confirmed on the surface of the first rare earth aluminate phosphor particle 1a.

Embodiments of the present disclosure include the rare earth aluminate phosphors, the light emitting devices, the projector, and the methods of manufacturing rare earth aluminate phosphors described below.

A rare earth aluminate phosphor which is a mode of the present invention and a light emitting device including the same can be suitably utilized as a light source for a projector, lighting fixture, LED display, backlight for liquid crystal display, and the like.

### REFERENCE NUMERALS

1: rare earth aluminate phosphor, 1a: first rare earth aluminate phosphor particle, 1b: second rare earth aluminate phosphor part, 50, 250: wavelength conversion member, 52, 252: substrate, 54, 254: wavelength conversion layer, 100: projector, 110: light source, 120: image display system, 130: projection optical system, 131: lens, 200: light emitting device, 210: light source, 222: lens, 224: dichroic mirror, 300: detector

What is claimed is:

1. A rare earth aluminate phosphor comprising:
a first rare earth aluminate phosphor particle having a composition represented by the formula (I) below,
a second rare earth aluminate phosphor part having a composition with a Ga molar ratio higher than a Ga molar ratio in one mole of the composition represented by the formula (I), the second rare earth aluminate phosphor part being present on a surface of first rare earth aluminate phosphor particle, wherein
a Ga content measured by X-ray fluorescence spectrometry in the rare earth aluminate phosphor is 0.5% by mass or higher and lower than 3.0% by mass when a total of at least one element R¹ selected from the group consisting of Y, La, Lu, Gd, and Tb; Ce; Al; and at least one element M¹ selected from the group consisting of Ga and Sc is 100% by mass.
(R¹₁₋ₙCeₙ)₃(Al₁₋ₘM¹ₘ)₅ₖO₁₂ (I)
(In the formula (I), R¹ is at least one element selected from the group consisting of Y, La, Lu, Gd, and Tb, M¹ is at least one element selected from the group consisting of Ga and Sc, and m, n, and k respectively satisfy 0≤m≤0.012, 0.001≤n≤0.017, and 0.95≤k≤1.10.)

2. A rare earth aluminate phosphor comprising:
a first rare earth aluminate phosphor particle having a composition represented by the formula (I) below,
a second rare earth aluminate phosphor part having a composition with a Ga molar ratio higher than a Ga molar ratio in one mole of the composition represented by the formula (I), the second rare earth aluminate phosphor part being present on a surface of first rare earth aluminate phosphor particle, wherein
a Ga content measured by X-ray fluorescence spectrometry in the rare earth aluminate phosphor is 0.5% by mass or higher and lower than 3.0% by mass when a total of at least one element R¹ selected from the group consisting of Y, La, Lu, Gd, and Tb; Ce; Al; and at least one element M¹ selected from the group consisting of Ga and Sc is 100% by mass, and
a first pixel total count is a total number of pixels of one or more of the first rare earth aluminate phosphor particles in an image captured by a scanning electron microscope,
a second total pixel count is a total number of pixels of Ga in one or more of the second rare earth aluminate phosphor parts on the surfaces of the one or more first rare earth aluminate phosphor particles in an image obtained by an energy dispersive X-ray fluorescence spectrometer,
a pixel percentage calculated by dividing the second total pixel count by the first total pixel count is in a range of 5.0% to 80.0%.
(R¹₁₋ₙCeₙ)₃(Al₁₋ₘM¹ₘ)₅ₖO₁₂ (I)
(In the formula (I), R¹ is at least one element selected from the group consisting of Y, La, Lu, Gd, and Tb, M¹ is at least one element selected from the group consisting of Ga and Sc, and m, n, and k respectively satisfy 0≤m≤0.012, 0.001≤n≤0.017, and 0.95≤k≤1.10.)

3. A rare earth aluminate phosphor according to claim 1 wherein
a combined composition of the first rare earth aluminate phosphor particles and the second rare earth aluminate phosphor parts is represented by the formula (II) below.
(R¹₁₋ₙCeₙ)₃(Al_{1-p-q}GaₚSc_{q})₅ₖO₁₂ (II)
(In the formula (II), R¹ is at least one element selected from the group consisting of Y, La, Lu, Gd, and Tb, and n, p, q, and k respectively satisfy 0.001≤n≤0.017, 0.009<p<0.034, 0≤q≤0.012, and 0.95≤k≤1.10.)

4. The rare earth aluminate phosphor according to claim 3 wherein p in the formula (II) satisfies 0.010≤p≤0.030.

5. The rare earth aluminate phosphor according to claim 1 wherein R¹ in the formula (I) includes Y as a prerequisite, and the Ga content measured by X-ray fluorescence spectrometry is 1.0% by mass or higher and lower than 3.0% by mass when the total of the element R¹, Ce, Al, and the element M¹ is 100% by mass.

6. The rare earth aluminate phosphor according to claim 3 wherein R¹ includes Y as a prerequisite, and p satisfies 0.012<p<0.034 in the formula (II).

7. The rare earth aluminate phosphor according to claim 1 wherein R¹ in the formula (I) includes Lu as a prerequisite, and the Ga content measured by X-ray fluorescence spectrometry is 0.5% by mass or higher and lower than 3.0% by mass when the total of the element R¹, Ce, Al, and the element M¹ is 100% by mass.

8. The rare earth aluminate phosphor according to claim 3 wherein R¹ includes Lu as a prerequisite, and p satisfies 0.010≤p<0.034 in the formula (II).

9. The rare earth aluminate phosphor according to claim 1 wherein a particle of the rare earth aluminate phosphor includes a plurality of second rare earth aluminate phosphor parts on the surface of one of the first rare earth aluminate phosphor particles.

10. The rare earth aluminate phosphor according to claim 9 wherein the plurality of second rare earth aluminate phosphor parts are sporadically located on the surface of one of the first rare earth aluminate phosphor particles.

11. The rare earth aluminate phosphor according to claim 1 wherein
a first pixel total count is a total number of pixels of one or more of the first rare earth aluminate phosphor particles in an image captured by a scanning electron microscope,
a second total pixel count is a total number of pixels of Ga in one or more of the second rare earth aluminate phosphor parts on the surfaces of the one or more first rare earth aluminate phosphor particles in an image obtained by an energy dispersive X-ray fluorescence spectrometer,
a pixel percentage calculated by dividing the second total pixel count by the first total pixel count is in a range of 5.0% to 80.0%.

12. The rare earth aluminate phosphor according to claim 1 wherein an average particle size of the rare earth aluminate phosphor including one or more of the second rare earth aluminate phosphor parts on the surfaces of a plurality of the first rare earth aluminate phosphor particles measured by the Fisher Sub-sieve Sizer Method is in a range of 15 μm to 35 μm.

13. The rare earth aluminate phosphor according to claim 1 wherein the rare earth aluminate phosphor including one or more of the second rare earth aluminate phosphor parts on the surfaces of a plurality of the first rare earth aluminate phosphor particles has a peak emission wavelength in a range of 450 nm to 580 nm in the emission spectrum when irradiated with excitation light having a peak emission wavelength in a range of 350 nm to 500 nm.

14. A light emitting device comprising the rare earth aluminate phosphor according to claim 1 and a light emitting element having a peak emission wavelength in a range of 350 nm to 500 nm.

15. The light emitting device according to claim 14 wherein the light emitting element is a semiconductor laser.

16. The light emitting device according to claim 14 further comprising:
a wavelength conversion member containing the rare earth aluminate phosphor; and
a motor which rotates the wavelength conversion member.

17. A projector comprising:
the light emitting device according to claim 16;
an image display system; and
a projection optical system.

18. A method of manufacturing a rare earth aluminate phosphor comprising:
providing a raw material mixture having a preparatory composition represented by the formula (I) below by mixing a compound containing at least one rare earth element R¹ selected from the group consisting of Y, La, Lu, Gd, and Tb, a compound containing Ce, a compound containing Al, and a compound containing at least one element M¹ selected as needed from Ga and Sc;
obtaining first rare earth aluminate phosphor particles having a composition represented by the formula (I) below by conducting a first heat treatment on the raw material mixture; and
obtaining a rare earth aluminate phosphor including, on the surfaces of the first rare earth aluminate phosphor particles, second rare earth aluminate phosphor parts having a composition with a Ga molar ratio higher than a Ga molar ratio in one mole of the composition represented by the formula (I) below by conducting a second heat treatment on the first rare earth aluminate phosphor particles and a compound containing Ga at a temperature lower than a temperature set in the first heat treatment, wherein
in conducting the second heat treatment, a mixing ratio of the compound containing Ga is 0.5 parts by mass or higher and lower than 5.0 parts by mass per 100 parts by mass of the first rare earth aluminate phosphor particles,
the second heat treatment is not conducted on the first rare earth aluminate phosphor particles together with the compound containing the rare earth element R¹, the compound containing Ce, the compound containing Al, and the compound containing Sc,
(R¹₁₋ₙCeₙ)₃(Al₁₋ₘM¹ₘ)₅ₖO₁₂ (I)
(In the formula (I), R¹ is at least one element selected from the group consisting of Y, La, Lu, Gd, and Tb, M¹ is at least one element selected from the group consisting of Ga and Sc, and m, n, and k respectively satisfy 0≤m≤0.012, 0.001≤n≤0.017, and 0.95≤k≤1.10).

19. The method of manufacturing a rare earth aluminate phosphor according to claim 18 wherein the rare earth aluminate phosphor has a Ga content of 0.5% by mass or higher and lower than 3.0% by mass measured by X-ray fluorescence spectrometry when a total of the rare earth element R¹, Ce, Al, and the element M¹ is 100% by mass.

20. The method of manufacturing a rare earth aluminate phosphor according to claim 18 wherein the rare earth element R¹ includes Y as a prerequisite, and a Ga content is 1.0% by mass or higher and lower than 3.0% by mass measured by X-ray fluorescence spectrometry when a total of the rare earth element R¹, Ce, Al, and the element M¹ is 100% by mass.

21. The method of manufacturing a rare earth aluminate phosphor according to claim 18 wherein the rare earth element R¹ includes Lu as a prerequisite, and a Ga content is 0.5% by mass or higher and lower than 3.0% by mass measured by X-ray fluorescence spectrometry when a total of the rare earth element R¹, Ce, Al, and the element M¹ is 100% by mass.
